(19) United States
(12) Patent Application Publication
(10) Pub. No.: US 2026/0052964 A1
(43) Pub. Date: Feb. 19, 2026

(54) SEMICONDUCTOR DEVICES AND METHODS FOR FABRICATION THEREOF

(71) Applicant: TAIWAN SEMICONDUCTOR MANUFACTURING COMPANY, LTD., Hsinchu (TW)

(72) Inventors: Yun-Sheng LI, Hsinchu (TW); Chih Hsin YANG, Hsinchu (TW); Mao-Nan WANG, Kaohsiung (TW); Kuan-Hsun WANG, Hsinchu (TW); Yang-Hsin SHIH, Hsinchu (TW); Chih-Chieh CHANG, Hsinchu (TW)

(21) Appl. No.: 18/976,547

(22) Filed: Dec. 11, 2024

Related U.S. Application Data
(60) Provisional application No. 63/684,399, filed on Aug. 18, 2024.

(51) Int. Cl. H01L 23/48; H01L 21/768; H01L 23/58; H10D 84/01

(52) U.S. Cl. CPC H01L 23/481; H01L 21/76898; H01L 23/585; H10D 84/0149

(57) ABSTRACT

Embodiments of the present disclosure provide a method for forming TSV structures. In some embodiments, buffering structures are formed adjacent dummy devices in the TSV region. By introducing buffering structures adjacent the end gate structures of the dummy device in the TSV region, residual metallic material may be eliminated, thereby, avoiding arcing in fabrication of TSV structures.

### CROSS-REFERENCE TO RELATED APPLICATIONS

This application claims priority to the U.S. Provisional Patent Application Ser. No. 63/684,399, filed Aug. 18, 2024, which is incorporated by reference in its entirety.

### BACKGROUND

A through silicon via (TSV) provides a pathway (e.g., for an electrical connection) between wafers stacked in a vertical direction in an electronic device. The TSV may facilitate an increased level of integration in packaging for electronic devices, such as three-dimensional integrated circuits (3DICs). A 3DIC may be formed by stacking two or more wafers, with one or more TSVs formed through at least one of the two or more wafers to provide a pathway to connect the two or more wafers to a substrate. TSVs may be formed in a wafer by forming a recess that extends partially through a substrate, and filling the recess with a conductive material, such as copper.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are views of a semiconductor device structure including a through silicon via (TSV) structure according to some embodiments of the present disclosure.

FIG. 2 is a flow chart of a method for manufacturing of a semiconductor device according to embodiments of the present disclosure.

FIGS. 3A, 3B, 4A, 4B, 5, 6, 7, 8, 9A, 9B, 9C, 10A, 10B, 11A, 11B, 12A, 12B, 13, 14, 15, 16, and 17 schematically illustrate various stages of manufacturing a semiconductor device according to embodiments of the present disclosure.

FIGS. 18A and 18B schematically demonstrate a semiconductor device structure according to one embodiment of the present disclosure.

FIGS. 19A and 19B schematically demonstrate a semiconductor device structure according to one embodiment of the present disclosure.

FIGS. 20A and 20B schematically demonstrate a semiconductor device structure according to one embodiment of the present disclosure.

FIGS. 21A and 21B schematically demonstrate a semiconductor device structure according to one embodiment of the present disclosure.

FIG. 22 is a flow chart of a method for manufacturing of a semiconductor device according to embodiments of the present disclosure.

FIGS. 23, 24, 25, 26, 27A, 27B, and 28 schematically illustrate various stages of manufacturing a semiconductor device according to embodiments of the present disclosure.

FIGS. 29A and 29B schematically demonstrate a semiconductor device structure according to one embodiment of the present disclosure.

FIGS. 30A and 30B schematically demonstrate a semiconductor device structure according to one embodiment of the present disclosure.

FIGS. 31A and 31B schematically demonstrate a semiconductor device structure according to one embodiment of the present disclosure.

FIGS. 32A and 32B schematically demonstrate a semiconductor device structure according to one embodiment of the present disclosure.

FIG. 33 schematically demonstrate a semiconductor device structure according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 154 degrees or at other orientations) and the spatially relative descriptors used herein may likewise be interpreted accordingly.

The foregoing broadly outlines some aspects of embodiments described in this disclosure. While some embodiments described herein are described in the context of FinFETs, implementations of some aspects of the present disclosure may be used in other processes and/or in other devices, such as planar FETs, nanosheet FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

In some embodiments, a through-substrate via (TSV) is formed in a region comprising dummy devices, buffering structures, and isolation material. The dummy devices may be formed during the same process with functional devices in other areas of the same substrate. The TSV is formed by forming and filling a TSV opening extending through a dummy area with dummy devices. It has been observed that metallic materials, such as metal gate, in the dummy devices may negatively impact the fabrication tools, for example by causing arcing. Therefore, a process, such as continuous poly on oxide definition (CPODE) process, may be performed in the dummy area so that the dummy devices do not include conductive materials, such as gate electrode layer. However, some polycrystalline material may remain in PODE (polycrystalline on oxide edge) after the CPODE process, resulting in formation of metal gate residue at the PODE.

According to embodiments of the present disclosure, buffering structures are inserted in an edge of the dummy area. The buffering structures may be polycrystalline fins parallel to the sacrificial gate structures outside the dummy areas. The buffering structures is positioned to the PODE to prevent incomplete removal in the PODE, thereby preventing metal gate residue formation in subsequent processes.

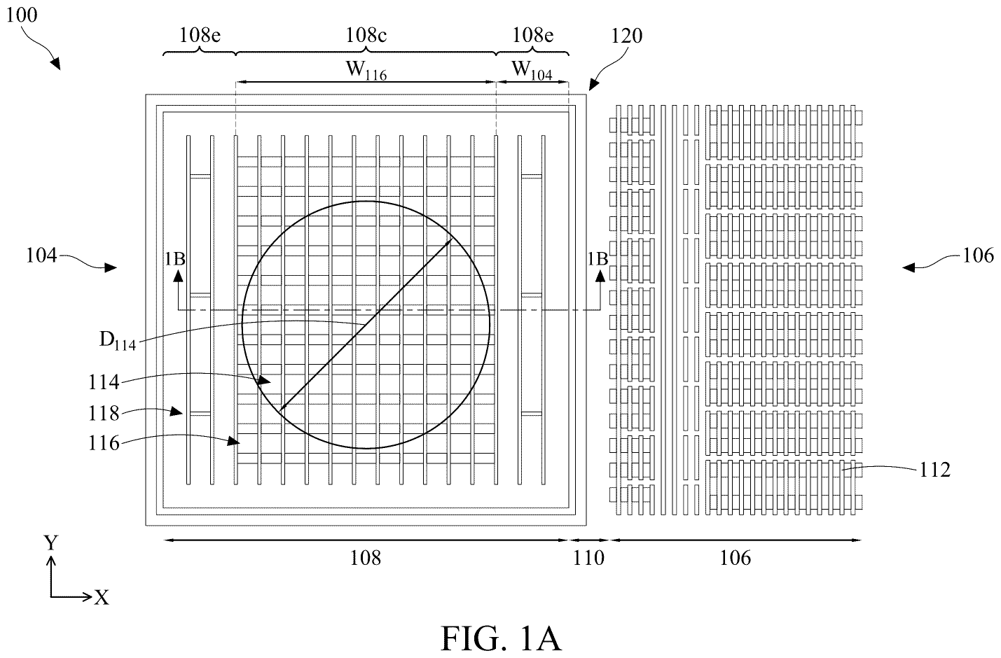

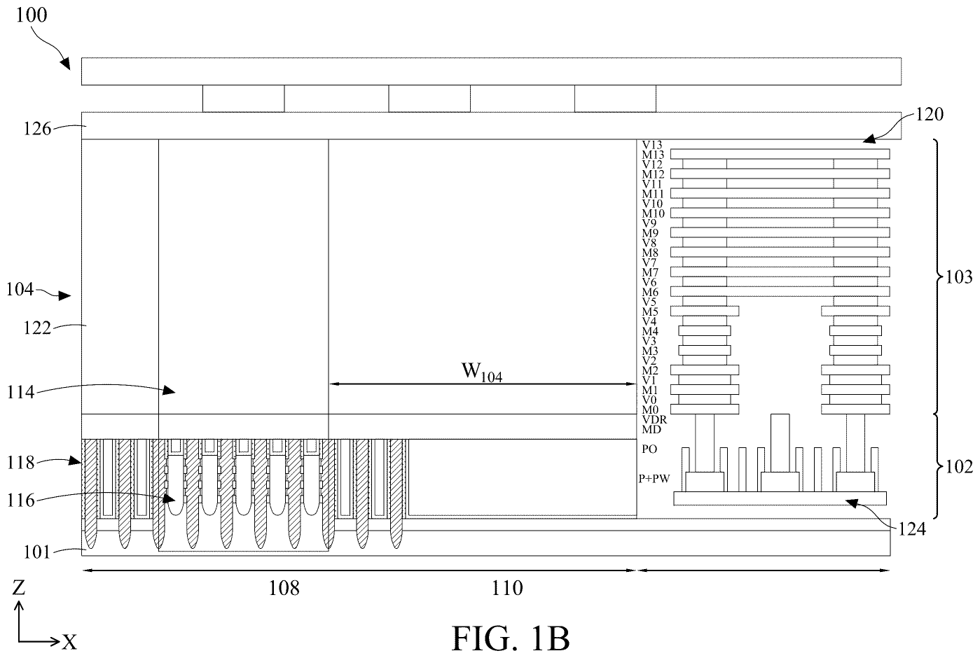

FIGS. 1A and 1B are views of a semiconductor device structure 100 in some embodiments. FIG. 1A is a top view of the semiconductor device structure 100, and FIG. 1B is a cross-sectional side view of the semiconductor device structure 100 along a 1A-1A line in FIG. 1A. The semiconductor device structure 100 may include a TSV area 104 disposed within a circuit area 106. The circuit area 106 includes functional and dummy devices. The TSV area 104 may include a boundary region 110 surrounding a TSV region 108. A TSV structure is formed in the TSV region 108. A guard ring 120 is formed in the boundary region. The guard ring 120 provides protection to the devices in the circuit area 106 from moisture and/or stress.

As shown in FIGS. 1A and 1B, the semiconductor device structure 100 includes a substrate 101, such as a semiconductor wafer or a semiconductor die. The substrate 101 may be a semiconductor substrate, such as silicon, doped or undoped, or an active layer of a semiconductor-on-insulator (SOI) substrate. The substrate 101 may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Active and/or passive devices 112, such as transistors, diodes, capacitors, resistors, etc., may be formed in and/or on the substrate 101.

As shown in FIG. 1B, a device layer 102 is formed on the substrate 101. An interconnect layer 103 formed over the device layer 102. The guard ring 120 includes conductive features formed in the device layer 102 and the interconnect layer 103. A TSV structure 114 is formed through the device layer 102, the interconnect structure 103, and the substrate 101 in the TSV area 102.

A plurality of devices 112 are formed in the device layer 102 at the circuit region 106. The plurality of devices 112 may include any suitable devices, such as transistors, diodes, imaging sensors, resistors, capacitors, inductors, memory cells, or a combination thereof. In some embodiments, the plurality of devices 112 are transistors, such as planar field effect transistors (FETs), FinFETs, nanostructure transistors, forksheet FETs, complementary FETs (CFETs), or other suitable transistors. In some embodiments, the plurality of devices 112 include standard cells (STD), such as logic gates, such as an AND gate, an OR gate, an XOR gate, a NOT gate, a NAND gate, a NOR gate, and an XNOR gate, and combinational logic circuits such as a multiplexer, a flip-flop, an adder, and a counter.

In the TSV region 108 of the device layer 102, a plurality of dummy devices 116 are formed in a central section 108c and buffering structures 118 are formed adjacent the dummy devices 116 in end sections 108e. The plurality of dummy devices 116 may include source/drain regions and dielectric materials formed in gate structures between the source/drain regions. The TSV structure 114 is formed through the plurality of dummy devices 116. In some embodiments, the buffering structures 118 includes gate-like structures without source/drain regions. In some embodiments, the buffering structures 118 is disposed adjacent the dummy devices to provide structural support to the gate structures in the dummy devices 116. The buffering structures 118 may be disposed along end gate structures of the dummy structures 116.

As shown in FIG. 1B, the interconnect structure 103 is disposed over the device layer 102 over the TSV area 104 and the circuit area 106. The interconnect structure 103 includes a plurality of dielectric layers 122, such as intermetal dielectric (IMD) layers. Over the circuit area 106 and the boundary region 110 of the TSV area 104, a plurality of conductive features are formed in the dielectric layers 122. The conductive features may be conductive lines or conductive vias. The conductive features may be made from one or more electrically conductive materials, such as metal, metal alloy, metal nitride, or silicide. For example, the conductive features are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof. Over the circuit area 106, the plurality of conductive features provide signal and power to the plurality of devices 112. Over the boundary region 110 of the TSV area 104, the plurality of conductive features form a conductive wall around the TSV region 108 providing isolation between the TSV area 104 and the circuit area 106. Within the TSV region 108 in the TSV area 104, the interconnect structure 103 includes dielectric layers without the conductive features.

The TVS structure 114 is disposed in the interconnect structure 103, the device layer 102, and the substrate 101 within the area defined by the dummy devices 116. The TVS structure 114 includes an electrically conductive material, such as metal, for example copper. As shown in FIG. 1A, the TVS structure 114 has a circular shape when viewed from the top. However, the TVS structure 114 may have any suitable shape, such as rectangular or square. In some embodiments, the TVS structure 114 has a diameter D₁₁₄ ranging from about 0.1 microns to about 10 microns, such as from about 1 micron to about 5 microns.

In some embodiments, the TSV structure 114 is formed after formation of the interconnect structure 103 by first etching through the interconnect structure 103, the device layer 102 and into the substrate 101 to form a TSV opening, then depositing a liner in the TSV opening, and then filling the TSV opening with a conductive material. The liner may include a dielectric material, such as an oxide or a nitride, and may be formed by a conformal process, such as atomic layer deposition (ALD). In some embodiments, a barrier layer (not shown) may be formed on the liner prior to filling the metal material. The barrier layer may include a metal or a metal nitride, such as Ti, TiN, Ta, TaN, or other suitable material. As shown in FIG. 1A, the TSV opening is disposed within the area of the dummy devices 116. In some embodiments, the dummy devices 116 may form in an area having a width W₁₁₆ along the x-direction. The width W₁₁₆ may be greater than the diameter D₁₁₄ to provide a tolerance for patterning overlay.

The guard ring 120 is formed around the TVS structure 114 to prevent water vapor and residual ions, e.g., produced during the process of forming the TSV structure 114. In some embodiments, the TSV structure 114 and the guard ring 120 may be at a distance W₁₀₄ from each other. In some embodiments, the distance W₁₀₄ is greater than 0.1 microns, from example in a range between 0.1 microns and 1.0 micron. The guard ring 120 may include one or more rings having a stack of conductive features disposed in the interconnect structure 103. In some embodiments, each conductive feature of the stack of conductive features is a closed-loop structure, unlike the conductive features in the interconnect structure 103, which are conductive lines or conductive vias. The width of the closed-loop structures may vary. The material of the guard ring 120 may be the same as the material of the conductive features in the interconnect structure 103. In some embodiments, the guard ring 120 is formed simultaneously with the conductive features in the interconnect structure 103.

In some embodiments, the guard ring 120 may be formed over dummy devices 124 formed in the boundary region 110 in the device layer 102. The dummy devices 124 may be devices, such as transistors, not electrically connected to a signal source, a power source, or any active devices. In some embodiments, a dummy device 124 is a transistor including a gate electrode, a source region, a drain region, and a channel region between the source region and the drain region. The dummy device 124 may be formed along with the active devices to improve loading effects. In some embodiments, the dummy devices 124 are not present, and the guard ring 120 includes a plurality of conductive features disposed in the interconnect structure 103.

The buffering structures 118 are formed in the device layer 102 between the dummy devices 116 and the dummy devices 124. In some embodiments, the buffering structures 118 may include one or more gate like structures disposed adjacent to the gate structures of the dummy devices 116 to reduce and even eliminating process non-uniformity occurred to outermost gate structures in the dummy devices 116. Additional conductive features 126, such as redistribution layers (RDLs), bonding pads and/or bonding structures, are formed over the interconnect structure 103.

In some embodiments, the distance W₁₀₄ corresponds to the width of the buffering structures 118. In some embodiments, a ratio of the distance W₁₀₄ over the width W₁₁₆ of the dummy devices 116 is in a range between about 0.2 and about 0.24. In some embodiments, as shown in FIG. 1B, the gate like structures in the buffering structures 118 and the gate structures of the dummy devices 116 may be replaced with isolation regions.

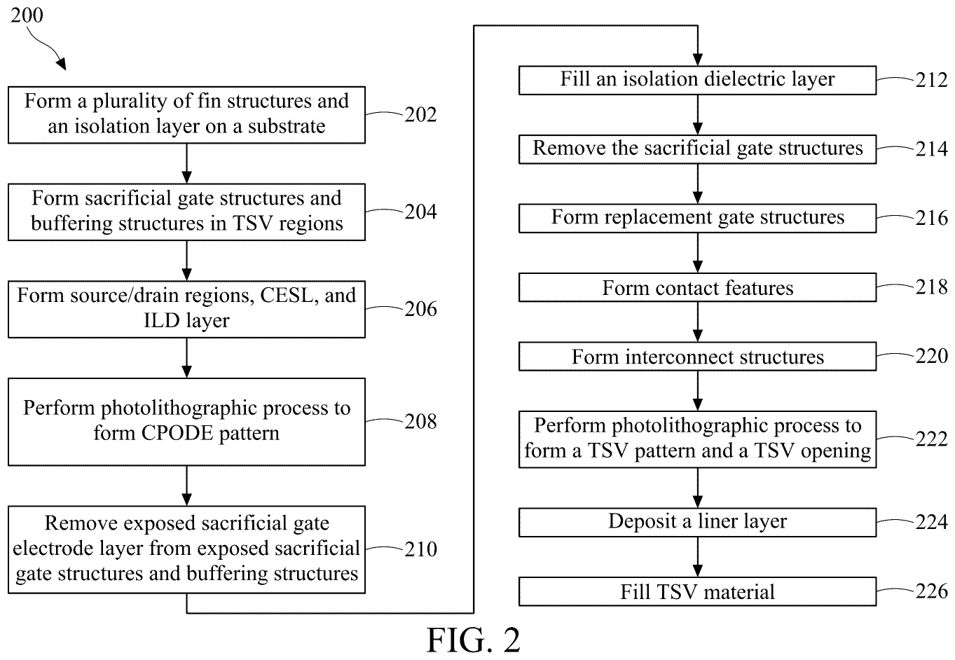

FIG. 2 is a flow chart of a method 200 for manufacturing of a semiconductor device according to embodiments of the present disclosure. The semiconductor device structure 100 may be fabricated with the method 200.

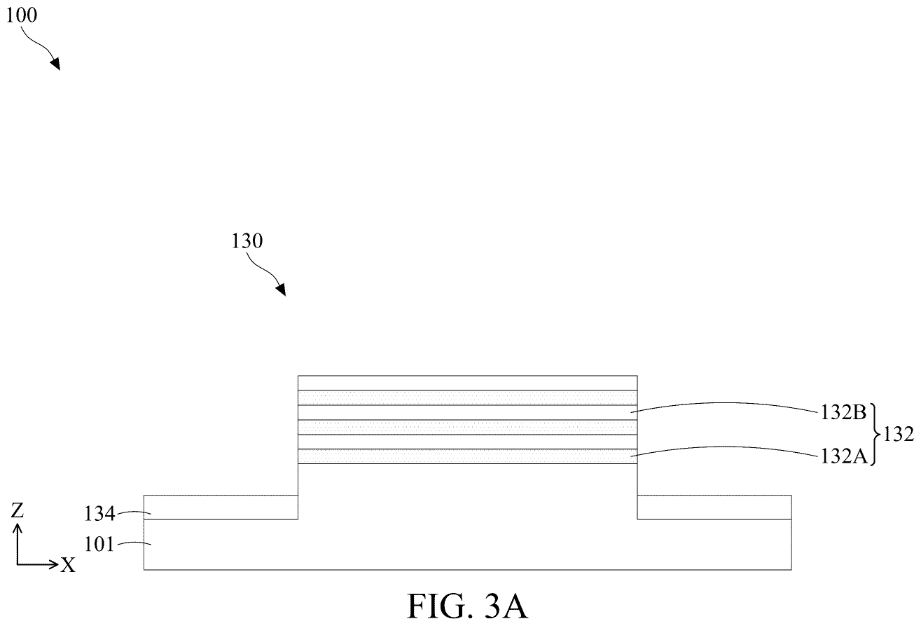

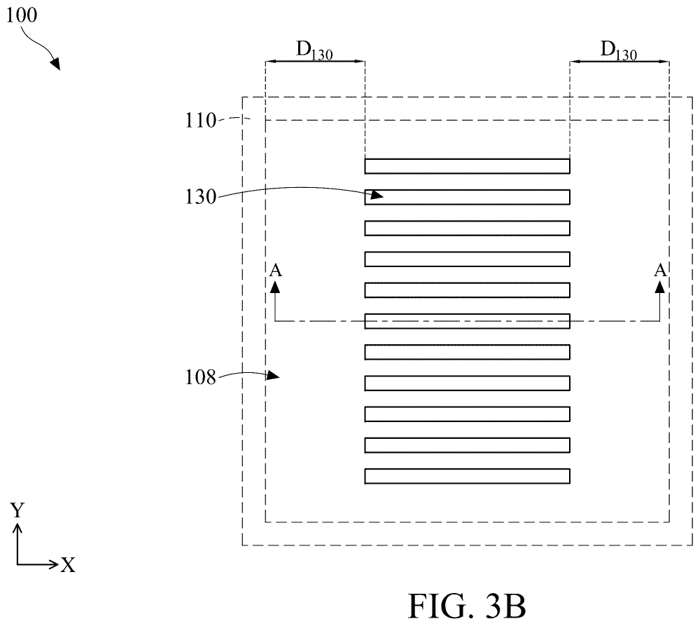

FIGS. 3A, 3B, 4A, 4B, 5, 6, 7, 8, 9A, 9B, 9C, 10A, 10B, 11A, 11B, 12A, 12B, 13, 14, 15, 16, and 17 schematically illustrate various stages of manufacturing the semiconductor device structure 100 according to embodiments of the present disclosure.

In operation 202 of the method 200, a plurality of fin structures 130 are formed on the semiconductor substrate 101, as shown in FIGS. 3A-3B. FIG. 3A is a cross-sectional view of the semiconductor device substructure 100 in a TSV region 108. FIG. 3B is a schematic top view of the semiconductor device structure 100 in the TSV region 108. FIG. 3A is a cross section alone the A-A line in FIG. 3B.

Referring to FIG. 3A, the fin structure 120 is a multilayer structure comprising a multilayer stack 132 formed on the substrate 101. In some embodiments, substrate 101 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. In some embodiments, the multilayer stack 132 is formed through a series of deposition processes for depositing alternating materials. In some embodiments, the multilayer stack 132 comprises first layers 132A formed of a first semiconductor material and second layers 132B formed of a second semiconductor material different from the first semiconductor material.

In some embodiments, the first semiconductor material of a first layer 132A is formed of or comprises silicon; germanium; a compound semiconductor including silicon carbide, gallium arsenide, gallium phosphide, indium phosphide, indium arsenide, and/or indium antimonide; an alloy semiconductor including silicon germanium (SiGe), gallium arsenide phosphide, aluminum indium arsenide, aluminum gallium arsenide, gallium indium arsenide, gallium indium phosphide, and/or gallium indium arsenide phosphide; the like, or combinations thereof. In some embodiments, the deposition of the first layers 132A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In some embodiments, the first layer 132A is formed to a first thickness in the range between about 30 A and about 300 A. However, any suitable thickness may be utilized while remaining within the scope of the embodiments.

Once the first layer 132A has been deposited over substrate 101, a second layer 132B is deposited over the first layer 132A. In some embodiments, the second layers 132B is formed of or comprises silicon; germanium; a compound semiconductor including silicon carbide, gallium arsenide, gallium phosphide, indium phosphide, indium arsenide, and/or indium antimonide; an alloy semiconductor including silicon germanium (SiGe), gallium arsenide phosphide, aluminum indium arsenide, aluminum gallium arsenide, gallium indium arsenide, gallium indium phosphide, and/or gallium indium arsenide phosphide; the like, or combinations thereof, in which the second semiconductor material being different from the first semiconductor material of first layer 132A. For example, in some embodiments in which the first layer 132A is silicon germanium, the second layer 132B may be formed of silicon, or vice versa. It is appreciated that any suitable combination of materials may be utilized for first layers 132A and the second layers 132B. In some embodiments, the second layer 132B is epitaxially grown on the first layer 132A using a deposition technique similar to that is used to form the first layer 132A. In some embodiments, the second layer 132B is formed to a similar thickness to that of the first layer 132A. The second layer 132B may also be formed to a thickness that is different from the first layer 132A. Once the second layer 132B has been formed over the first layer 132A, the deposition process is repeated to form the remaining layers in multilayer stack 132, until a desired topmost layer of multilayer stack 132 has been formed. In some embodiments, first layers 132A have thicknesses the same as or similar to each other, and second layers 132B have thicknesses the same as or similar to each other.

The first layers 132A may also have the same thicknesses as, or different thicknesses from, that of second layers 132B. In some embodiments, the first layers 132A are removed in the subsequent processes, and are alternatively referred to as sacrificial layers 132A throughout the description. In accordance with alternative embodiments, the second layers 132B are sacrificial, and are removed in the subsequent processes.

After deposition the multilayer stack 132, the fin structures 130 are formed using one or more patterning and etching processes to pattern the multilayer stack 132 and a portion of the underlying substrate 101. For example, the fin structures 130 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 130.

Isolation regions 134, which are also referred to as Shallow Trench Isolation (STI) regions throughout the description, are then formed around lower portions of the fin structures 130. In some embodiments, a dielectric liner, not shown, which may be a conformal dielectric layer, is deposited. The dielectric liner may comprise silicon oxide, silicon nitride, or the like, and may be formed using, for example, ALD, High-Density Plasma Chemical Vapor Deposition (HDPCVD), CVD, or the like. A dielectric material is deposited over the dielectric liner. The dielectric material may comprise silicon oxide or other dielectric material comprising carbon, nitrogen, or the like, and may be formed using Flowable Chemical Vapor Deposition (FCVD), spin-on coating, HDPCVD, ALD, CVD, or the like. A planarization process, such as a Chemical Mechanical Polish (CMP) process or a mechanical grinding process, is performed to polish and level the top surface of the dielectric material and dielectric liner. The STI regions 134 are then formed by recessing the dielectric material, so that the top portions of the fin structures 130 protrude over the STI regions 134.

FIGS. 3A-3B illustrate the TSV region 108. It should be noted that the fin structures are also formed in other regions on the substrate 101 simultaneously. For example, fin structures may be formed in the circuit area 106 outside the TSV region 108 for functional devices and dummy devices, and the boundary regions 110 around the TSV region 108 if dummy devices are to be formed under the guard ring 120.

As shown in the FIG. 1B, the fin structures 130 formed within the TSV region 108 along the x-direction. In some embodiments, the fin structures 130 in the TSV region 108 are disposed in a central region of the TSV region 108. Ends of the fin structures 130 may have a distance D₁₃₀ from the boundary region 110 along the x-direction. In some embodiments, the distance D₁₃₀ is greater than 0.1 microns.

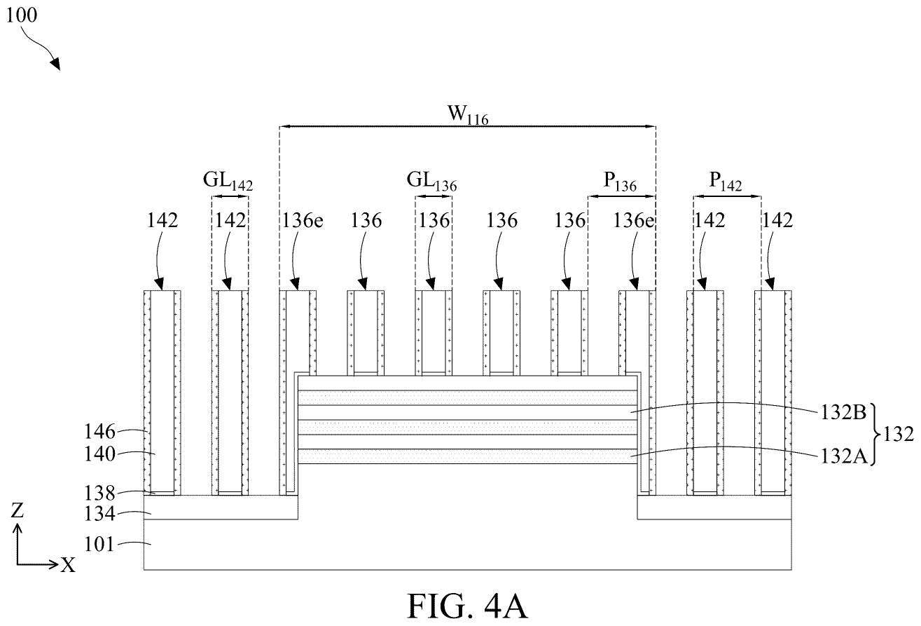

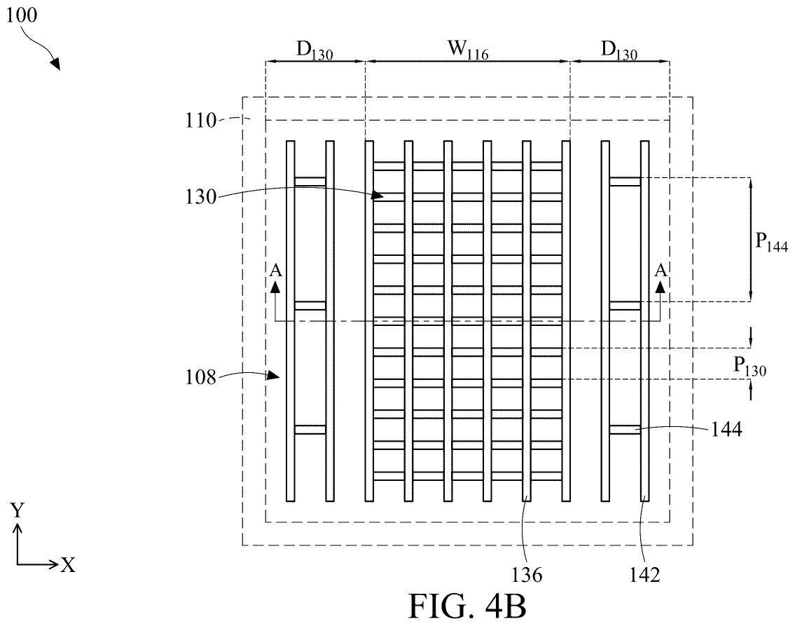

In operation 204, sacrificial gate structures 136 and buffering structures 142 are formed in the TSV region 108, as shown in FIGS. 4A and 4B. After formation of the fin structures 130, a sacrificial gate dielectric layer 138 is conformally deposited over the fin structures 142 and the isolation regions 134. In some embodiments, the sacrificial gate dielectric layer 138 is deposited, for example, using a conformal deposition process such as ALD, CVD, or the like. The sacrificial gate dielectric layer 138 may be formed of or comprise silicon oxide in some embodiments.

A sacrificial gate electrode layer 140 is the deposited over the sacrificial gate dielectric layer 138. In some embodiments, the sacrificial gate electrode layer 140 is formed of or comprises polysilicon, amorphous silicon, or the like. In some embodiments, a hard mask layers (not shown) is formed over sacrificial gate electrode layer 140. The hard mask layers may be formed of silicon nitride, silicon oxide, silicon carbonitride, silicon oxycarbonitride, or the like, or multilayers thereof.

The sacrificial gate electrode layer 140 and sacrificial gate dielectric layer 138 are patterned in etching processes, hence forming the sacrificial gate stacks 136 and the buffering structures 142. A gate spacer layer 146 is deposited, for example, through a conformal deposition process such as ALD, CVD, or the like over the sacrificial gate stacks 136 and the buffering structures 142. In some embodiments, gate sidewall spacer 146 is formed of a dielectric material such as silicon nitride, silicon oxide, silicon carbonitride, silicon oxynitride, silicon oxycarbonitride, or the like, and may have a single-layer structure or a multilayer structure including a plurality of dielectric layers. After the deposition process, an anisotropic etching process(es) may be performed to etch the horizontal portions of gate sidewall spacer 146, leaving vertical portions of gate sidewall spacer 146 unremoved. The remaining portions of the dielectric layer(s) are referred to as gate sidewall spacers 146.

As shown in FIG. 4B, the sacrificial gate stacks 136 are formed substantially perpendicular to the fin structures 130, or along the y-direction. In the TSV region 108, the sacrificial gate stacks 136 are formed over the fin structures 130. A plurality of sacrificial gate stacks 136 are arranged in parallel along the length of the fin structures 130. Each of the sacrificial gate stacks 136 has a gate length GL₁₃₆ in the x-direction. The plurality of sacrificial gate stacks 136 are arranged in a pitch P₁₃₆ in the x-direction. In some embodiments, end portion of the fin structures 130 are covered by two end sacrificial gate stacks 136e, as shown in FIG. 1A. In conventional process, the end sacrificial gate stacks 136e are patterned with a greater gate length than the sacrificial gate stacks 136 in the interior area to main upright position during patterning and etch processing. However, the additional gate length in the end sacrificial gate stacks 136 may result in residual gate electrode material, which could cause arcing during process of TSV formation.

The buffering structures 142 are gate stack like structures formed adjacent the end sacrificial gate stacks 136e. The buffering structures 142 may be positioned adjacent the end sacrificial gate stacks 136e so that the end sacrificial gate stacks 136e may have the same gate length as the other sacrificial gate stacks 136 without falling down during processing, hence, without residual electrode material to cause arcing.

Each buffering structure 142 may be a fin-like structure disposed on the isolation region 134. The buffering structure 142 may include the sacrificial gate dielectric layer 138 disposed on the isolation region 134, and the sacrificial gate electrode layer 140 disposed on the sacrificial gate dielectric layer 138. The number of buffering structures 142 may be sufficient to provide the structural support to the end sacrificial gate stacks 136e. In some embodiments, the buffering structures 142 may be two or more.

The buffering structure 142 has a gate length GL₁₄₂ in the x-direction. In some embodiments, the gate length GL₁₄₂ may be the same as the GL₁₃₆ in the x-direction. In some embodiments, the gate length GL₁₄₂ are the same for all the buffering structures 142. In other embodiments, the gate length GL₁₄₂ may vary for different buffering structures 142. For example, the gate length GL₁₄₂ for the buffering structure 142 closer to the sacrificial gate stacks 136 may be smaller for the buffering structure 142 farther away from the sacrificial gate stacks 136.

The buffering structures 142 may include two or more gate like stacks arranged in a pitch P142. In some embodiments, the pitch P142 of the buffering structures 142 may be substantially the same of the pitch P136 of the sacrificial gate stacks 136. For example, the buffering structures 142 and the sacrificial gate stacks 136 are arranged at the same pitch with in the TSV region 108. In other embodiments, the pitch P142 of the buffering structures 142 may be larger than the pitch 136.

In some embodiments, one or more bridging structures 144 may be formed between the buffering structures 142. The bridging structures 144 may be a fin-like structure disposed on the isolation region 134, along the x-direction. The bridging structures 144 may include the sacrificial gate dielectric layer 138 disposed on the isolation region 134, and the sacrificial gate electrode layer 140 disposed on the sacrificial gate dielectric layer 138. The bridging structures 144 may be arranged to provide the structural support to the buffering structures 142 so that the buffering structures 142 maintain upright during processing. The buffering structures 144 and the buffering structures 142 may be formed at the same time.

The bridging structures 144 may be arranged in a pitch P144 in the y-direction, as shown in FIG. 4B. In some embodiments, the pitch P144 of the bridging structures 144 may be in a range between about 2 time and 10 times of a pitch P130 for the fin structures 130.

It should be noted that the sacrificial gate stacks 136 are also formed in other regions on the substrate 101 simultaneously. For example, sacrificial gate stacks 136 may be formed in the circuit area 106 outside the TSV region 108 for functional devices and dummy devices, and the boundary regions 110 around the TSV region 108 if dummy devices are to be formed under the guard ring 120.

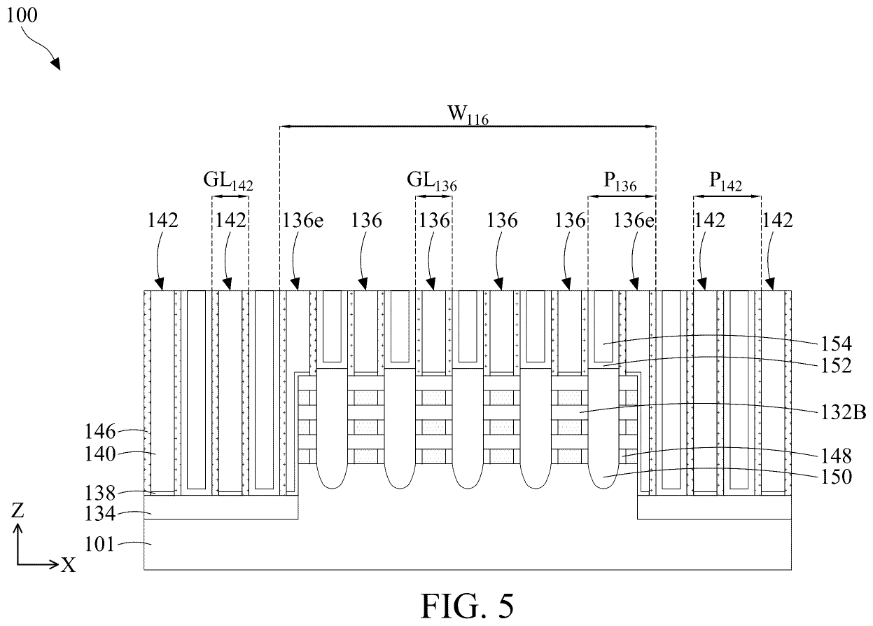

In operation 206, inner spacers 148, source/drain regions 150, Contact Etch Stop Layer (CESL) 152 and Inter-Layer Dielectric (ILD) 154 are formed, as shown in FIG. 5. In some embodiments, portions of fin structures 130 that are not directly underlying sacrificial gate stacks 136 and gate sidewall spacers 146 are recessed through an etching process to form source/drain recesses, which are between the un-etched portions of fin structures 130. For example, a dry etch process may be performed using C2F6, CF4, SO2, the mixture of HBr, Cl2, and O2, the mixture of HBr, Cl2, O2, and CH2F2, or the like to etch the fin structures 130.

After the formation of source/drain recesses, the sacrificial semiconductor layers 132A are laterally recessed to form lateral recesses, which are recessed from the edges of the respective overlying and underlying second semiconductor layers 132B. The lateral recessing of sacrificial semiconductor layers 132A may be achieved through a wet etching process using an etchant that is more selective to the material (for example, silicon germanium (SiGe)) of sacrificial semiconductor layers 132A than the material (for example, silicon (Si)) of the second semiconductor layers 132B and substrate 101. For example, in an embodiment the sacrificial semiconductor layers 132A are formed of silicon germanium and the second semiconductor layers 132B are formed of silicon, the wet etching process may be performed using an etchant such as hydrochloric acid (HCl). In accordance with alternative embodiments, the lateral recessing of sacrificial semiconductor layers 132A is performed through an isotropic dry etching process or a combination of a dry etching process and a wet etching process.

The inner spacers 148 are formed by first depositing a spacer layer extending the lateral recesses, and performing an etching process to remove the portions of inner spacer layer outside of lateral recesses, thus leaving inner spacers 148 in the lateral recesses. The inner spacers 148 may be formed of or comprise silicon oxycarbonitride, silicon oxynitride, silicon oxycarbide, silicon carbonitride, or the like. In some embodiments, the etching of the spacer layer may be performed through a wet etching process, in which the etching chemical may include H2SO4, diluted HF, ammonia solution (NH4OH, ammonia in water), or the like, or combinations thereof.

The epitaxial source/drain regions 150 are formed in source/drain recesses. The epitaxial source/drain region 150 may refer to a source or a drain, individually or collectively dependent upon the context. In some embodiments, the source/drain regions 150 may exert stress on the second semiconductor layers 132B, which are used as the channels of the corresponding nanostructure transistors, thereby improving performance. When the resulting transistors are n-type transistors, epitaxial source/drain regions 150 are formed to be n-type by doping an n-type dopant. For example, the n-type source/drain regions 150 may be formed of or comprise silicon phosphorous (SiP), silicon carbon phosphorous (SiCP), or the like. When the resulting transistors are p-type transistors, epitaxial source/drain regions 150 are formed to be p-type by doping a p-type dopant. For example, the p-type source/drain regions 150 may be formed of or comprise silicon germanium boron (SiGeB), silicon boron (SiB), or the like.

The CESL 152 may be formed of silicon oxide, silicon nitride, silicon carbonitride, or the like, and may be formed using CVD, ALD, or the like. The ILD 154 may include a dielectric material formed using, for example, FCVD, spin-on coating, CVD, or any other suitable deposition method. The ILD 154 may be formed of an oxygen-containing dielectric material, which may include a silicon-oxide, Phospho-Silicate Glass (PSG), Baro-Silicate Glass (BSG), Boron-Doped Phospho-Silicate Glass (BPSG), Undoped Silicate Glass (USG), or the like. The formation of the CESL 152 and the ILD 154 include depositing a conformal CESL 152, depositing ILD 154, and performing a planarization process.

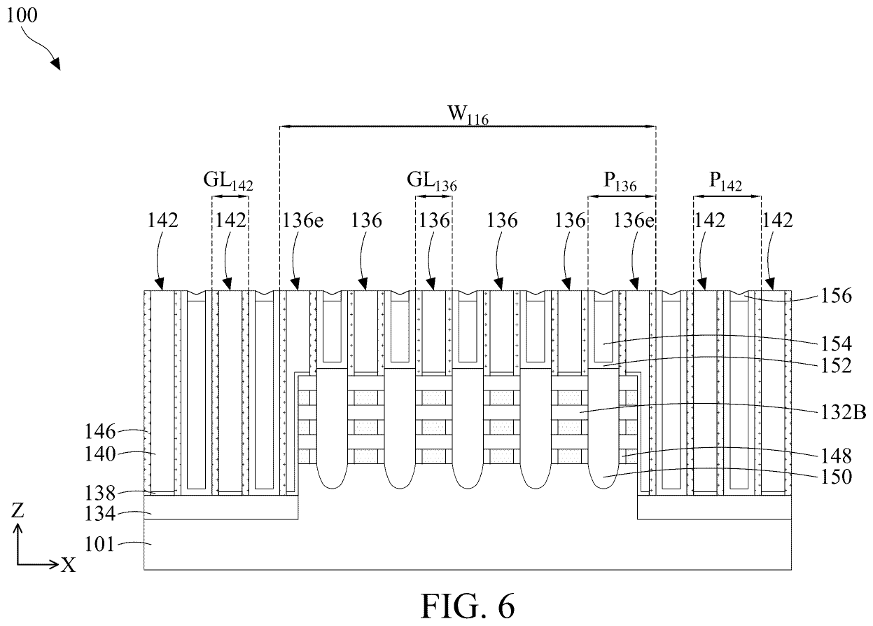

In some embodiments, cap layer 156 is formed over the ILD 154, as shown in FIG. 6. The cap layer 156 may provide protection to the ILD 154 during the subsequent process. The cap layer 156 may be formed of or comprise silicon nitride, silicon oxynitride, silicon oxycarbide, or the like. The formation process may include recessing ILD 154 to form recesses, depositing the corresponding dielectric material into the recesses, and performing a planarization process.

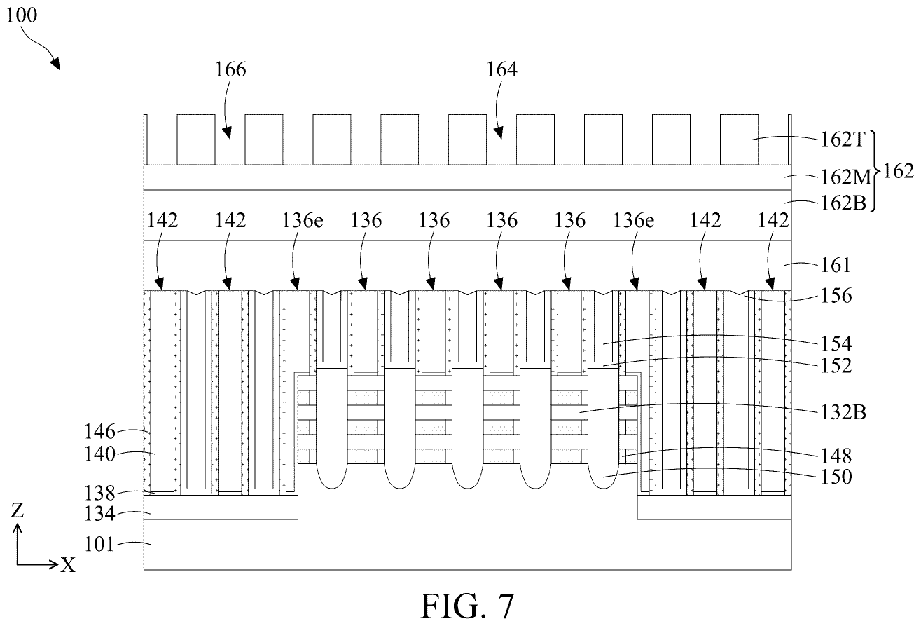

In operations 208, 210, and 212, isolation regions 158 are formed in the TSV regions 108, as illustrated in FIGS. 7, 8, and 9. The isolation regions 158, 160 are formed in the TSV region 108. The isolation regions 158 are formed in place of the sacrificial gate stacks 136, and the fin structures 130, the isolation region 134, and the substrate 101 underneath the sacrificial gate stacks 136. The isolation regions 158 cut through the fin structures 130 to electrically isolate the fin structures 130. The isolation regions 156 may also be referred to as Cut-Poly on Diffusion Edge (CPODE) regions since the formation process involves the cutting of polysilicon dummy gate electrode on the edge of active regions. The isolation regions 160 are formed in place of the buffering structures 142, and the isolation region 134 and the substrate 101 underneath the buffering structures 142.

In operation 208, a CPODE pattern is formed over the TSV region 108, as shown in FIG. 7. A deposition of hard mask 161 and etching mask 162. In some embodiments, hard mask 161 is formed of or comprises silicon nitride, silicon oxynitride, or the like. In some embodiments, etching mask 162 is a tri-layer etching mask, which includes a bottom layer 162B, a middle layer 162M, and a top layer 162T. The bottom layer 162B may be formed of a cross-linked photoresist. The middle layer 162B may be formed of an inorganic dielectric material. The top layer 162B is formed of a patterned photoresist, which includes openings 164, 166 patterned therein. The openings 164 are aligned with the sacrificial gate stacks 136 and the openings 166 are aligned with the buffering structures 142.

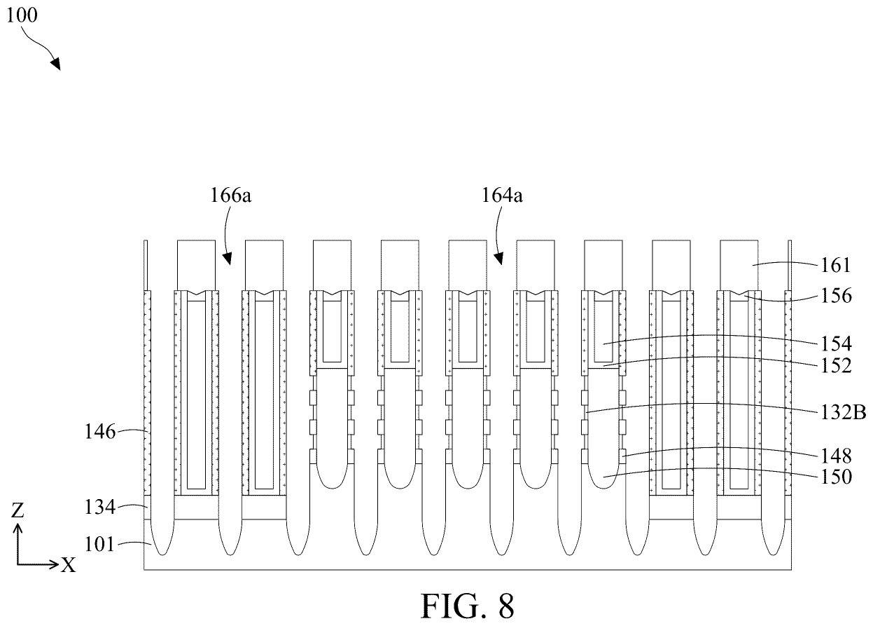

In operation 210, trenches 164a and 166a are formed through various layers to the substrate 201 using the openings 164, 166 in the patterned photoresist layer using one or more etching processes, as shown in FIG. 8. In some embodiments, the top layer 162T is used as an etching mask to etch the middle layer 162M and the bottom layer 162B. During the etching process, the top layer 162T and possibly middle layer 162M may be consumed, leaving a patterned bottom layer 162B. In this manner, the pattern may be transferred from the top layer 162T to the bottom layer 162B. The remaining etching mask 162 is then used to etch the hard mask 161, such that the openings 164, 166 are further transferred into hard mask 161. The remaining etching mask 162 is then removed, with the patterned hard mask 161 remaining. The patterned hard mask 161 is then used as an etching mask to etch the underlying structure to form trenches 164a and 166a.

The sacrificial gate electrode layer 140 is first etched. In some embodiments, the etching process is anisotropic, such that the openings 164a, 166a may have substantially vertical sidewalls. The etching of sacrificial gate electrode layer 140, when formed of polysilicon or amorphous silicon, may be performed using fluorine (F2), Chlorine (Cl2), hydrogen chloride (HCl), hydrogen bromide (HBr), Bromine (Br2), C2F6, CF4, SO2, the like, or combinations thereof. After etching of the sacrificial gate electrode layer 140, the sacrificial gate dielectric layer 130 and any native oxide formed on the surfaces of multilayer stacks 132 are removed through an etching process. The corresponding process may also be referred to as a dielectric break-through process. In some embodiments, the etching may be performed using CF4, Ar, and/or the like, and the etching may have a low selectivity. Next, multilayer stacks 132 are etched and semiconductor substrate 101 are etched. As shown in FIG. 8, the underlying bulk portion of substrate 101 underlying STI regions 134 are also etched. In some embodiments, the etching process includes a selective etch that has a high etching selectivity between semiconductor materials and dielectric materials. Accordingly, the inner spacers 148, which are revealed in the etching process, are not etched.

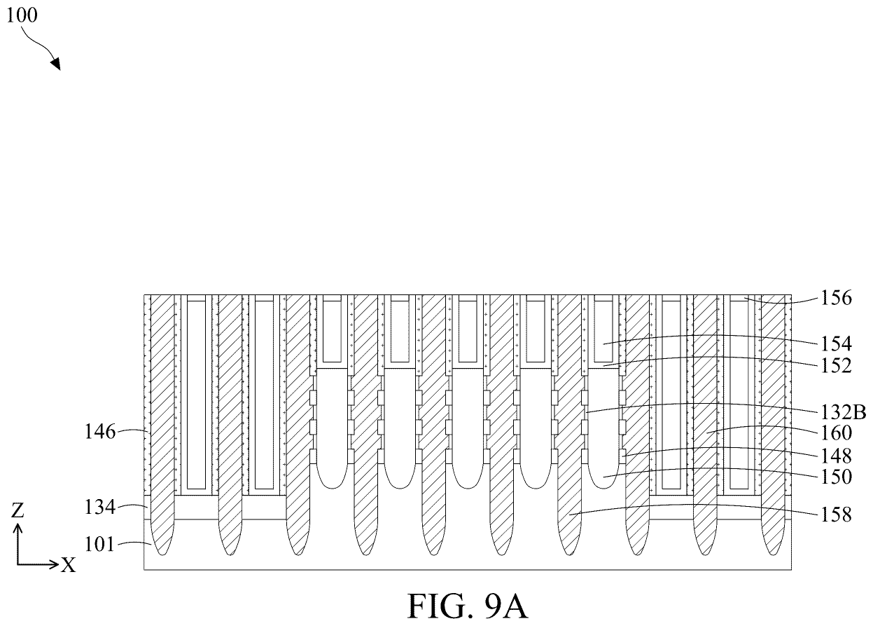

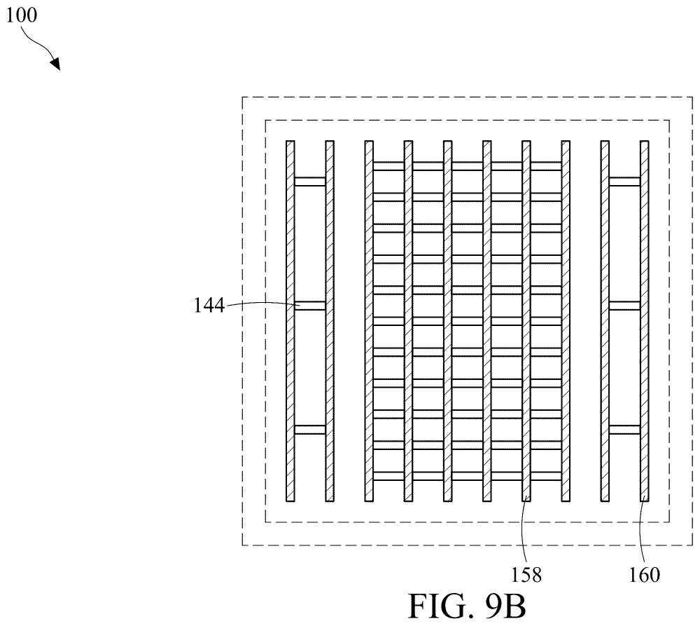

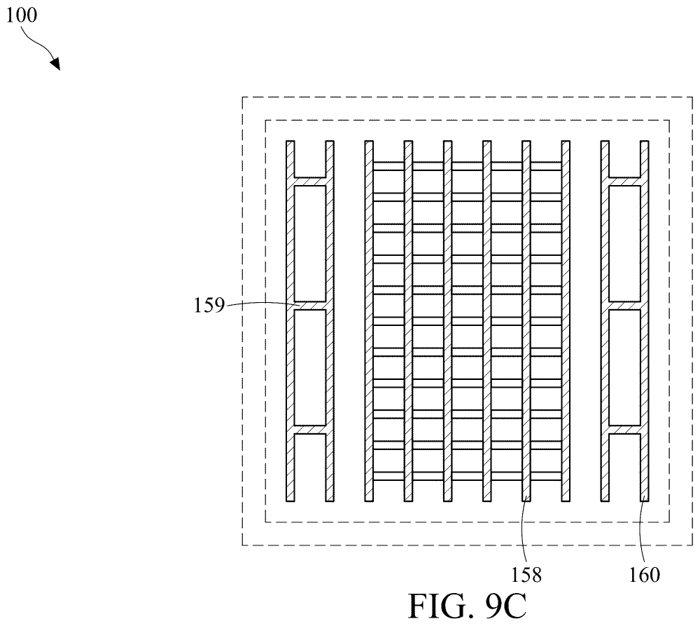

In operation 212, the trenches 166a, 164a are filled with dielectric material forming the isolation regions 158, 160, as shown in FIGS. 9A and 9B. In some embodiments, one or more dielectric layers may be deposited in the trenches The deposition process may deposit one or more dielectric layers in the trenches 164a, 166a. In some embodiments, the dielectric layers include a dielectric liner and a dielectric fill layer (not separately illustrated). The dielectric liner may be formed of or comprise silicon oxide. The dielectric fill layer may be formed of or comprise silicon nitride. Other materials such as silicon carbide, silicon oxynitride, silicon carbonitride, silicon oxycarbonitride, or the like may also be used to form the dielectric layers. In some embodiments, a planarization process (e.g., a CMP process, grinding process, or the like) may be performed to remove excess dielectric layer material, with remaining portions of the dielectric layers forming the isolation regions 158, 160. In some embodiments, the planarization process removes remaining portions of the hard mask 161.

The trenches 166a, 164a may have similar or different depths because of different layers are involved in the etching processes. Because the end gate sacrificial stacks 136e and the sacrificial gate stacks 136 in the interior location have the same dimension, the isolation regions 158 replacing the end gate sacrificial stacks 136e have the same dimension as the isolation regions 158 from the interior gate sacrificial gate stacks 136, without generating any voids. Voids in the isolation regions 158 may cause gate electrode material to fill therein and causing arcing in the subsequent processes.

In some embodiments, as shown in FIG. 9B, the bridging structures 144 remains between the isolation regions 160. In other embodiments, as shown in FIG. 9C, the bridging structures 144 are also removed and replaced by isolation regions 159 in the COPDE process. The isolation regions 159 are disposed between the isolation regions 160.

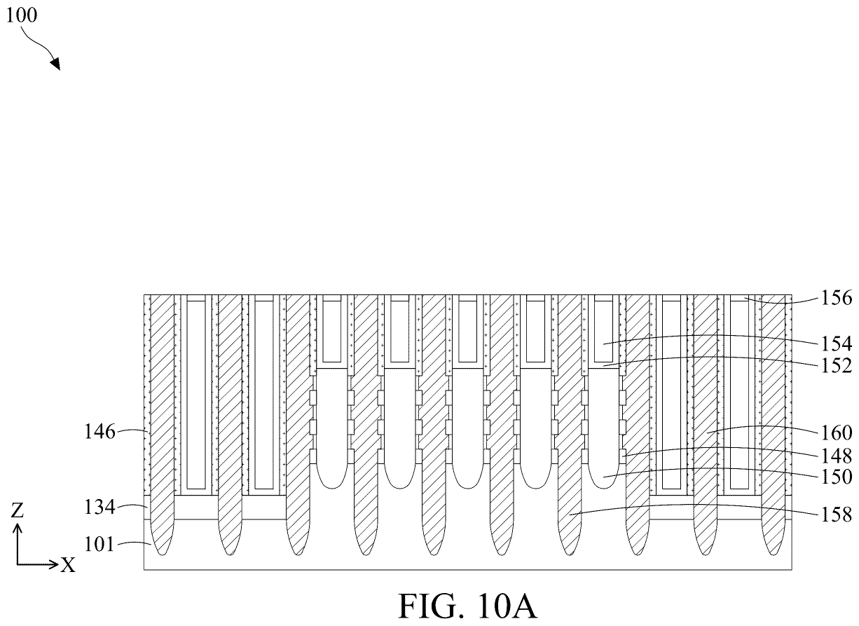

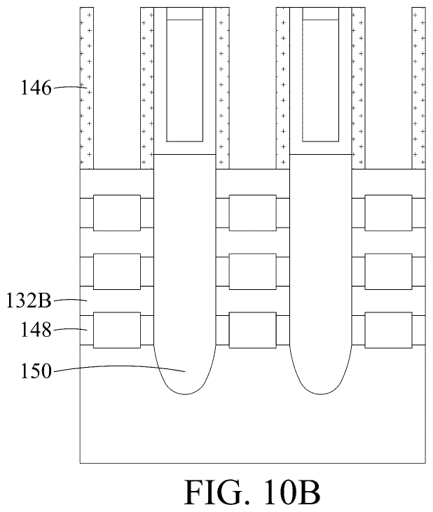

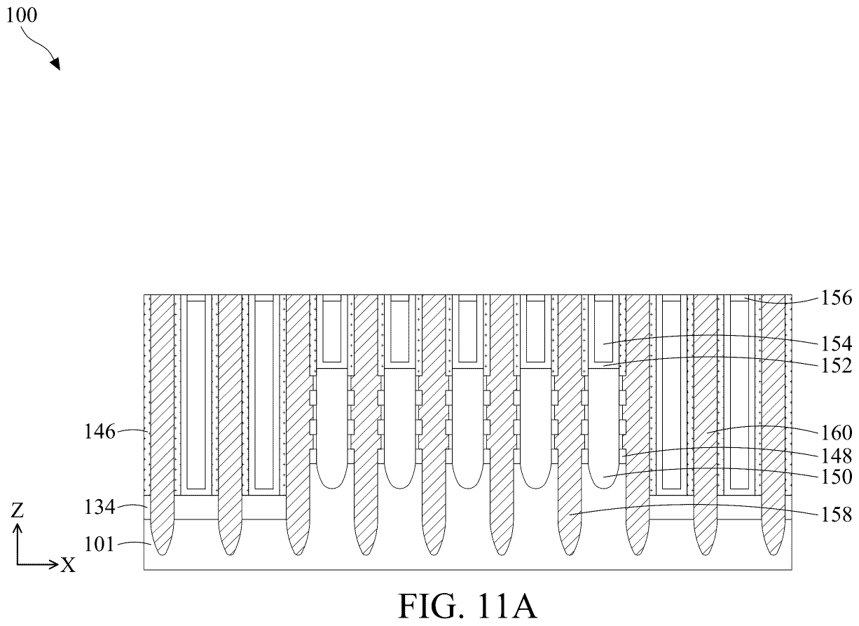

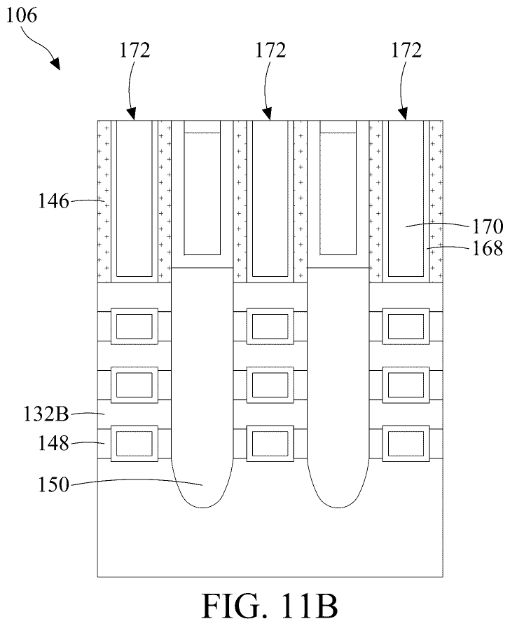

In operations 214 and 216, replacement gate structures 172 are formed, as shown in FIGS. 10A-10B and 11A-11B. FIGS. 10A, 11A are cross-sections of the TSV region 108. FIGS. 10B, 11B are cross sections of the device area 106. A replacement gate process is a process sequence to replace the sacrificial gate stacks 136 with the gate structures 172. In the TSV regions 108, the sacrificial gate stacks 136 are removed in the previous operations, therefore, no structural changes in operations 214, 216. The replacement gate process is shown in the cross section of the device area 106.

In operation 214, the sacrificial gate stacks 136 and sacrificial layers 132A in the device area 106 are removed, as shown in FIG. 10B. In some embodiments, the sacrificial gate stack 136 are removed by an anisotropic dry etch process that selectively etches the materials of the sacrificial gate stack s136. The sacrificial layers 132A may then be removed by performing an isotropic etching process such as wet etching or the like using etchants which are selective to the materials of the sacrificial layers 132A. The etching processes form gate recesses that expose surfaces of the second semiconductor layers 132B and which may surround the second semiconductor layers 132B.

In operation 216, gate dielectric layers 168 and gate electrode layer 170 are deposited to form the replacement gate structures 172, as shown in FIG. 11B. In some embodiments, the gate dielectrics layers 168 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectrics layers 168 include a high-k dielectric material, and in these embodiments, the gate dielectrics layers 168 may have a k value greater than about 7.0, and may include a metal oxide or a silicate of hafnium, aluminum, zirconium, lanthanum, manganese, barium, titanium, lead, and combinations thereof. The formation methods of the gate dielectrics layers 168 may include molecular-beam deposition (MBD), ALD, PECVD, and the like.

The gate electrode layer 170 are deposited over the gate dielectrics layers 168, respectively, and fill the remaining portions of the gate recesses. The gate electrode layer 170 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrode layer 170 are illustrated in FIG. 11B, the gate electrode layer 170 may comprise any number of liner layers, any number of work function tuning layers, and a fill material. Any combination of the layers which make up the gate electrode layer 170 may be deposited between adjacent ones of the second semiconductor layers 132B. The gate dielectrics layers 168 and the gate electrode layer 170 together may be considered replacement gate structures 172.

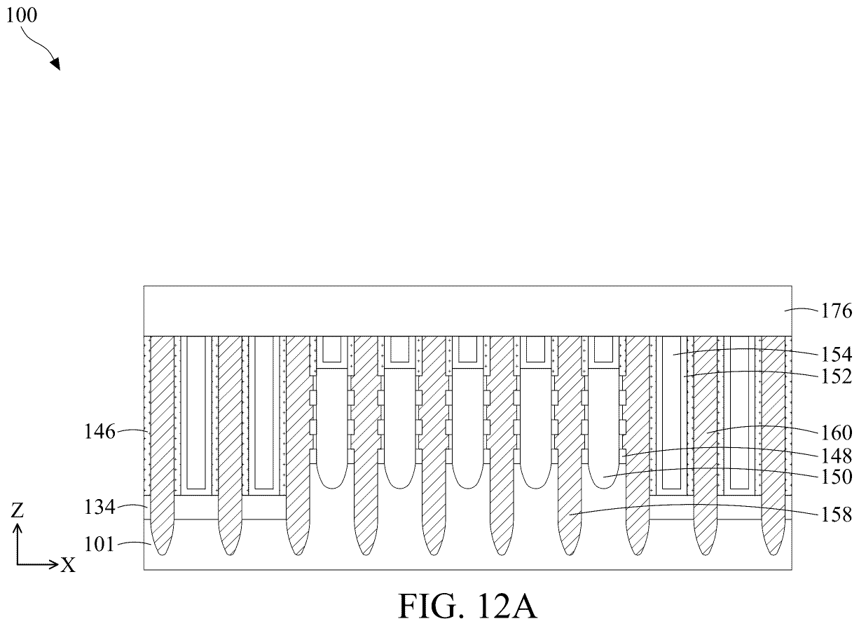

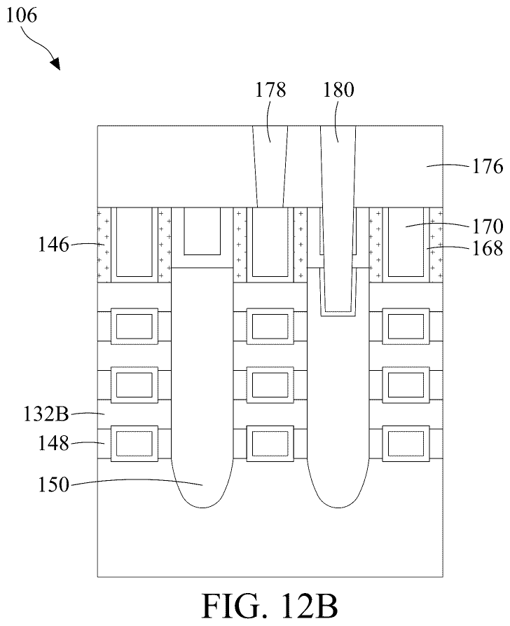

In operations 218, gate contact features 178 and source/drain contact features 180 are formed, as shown in FIGS. 12A and 12B. In some embodiments, a planarization process may be performed to remove the cap layer 156 and expose the ILD 154. A second ILD 176 may be deposited over the gate structures 172. Contact openings may be formed expose the source/drain regions 150 and the gate electrode 170. Conductive materials may be filled in the contact openings to form the gate contact features 178 and the source/drain contact features 180. No source/drain contact features 180 are formed over the source/drain regions 150 in the TSV region 108.

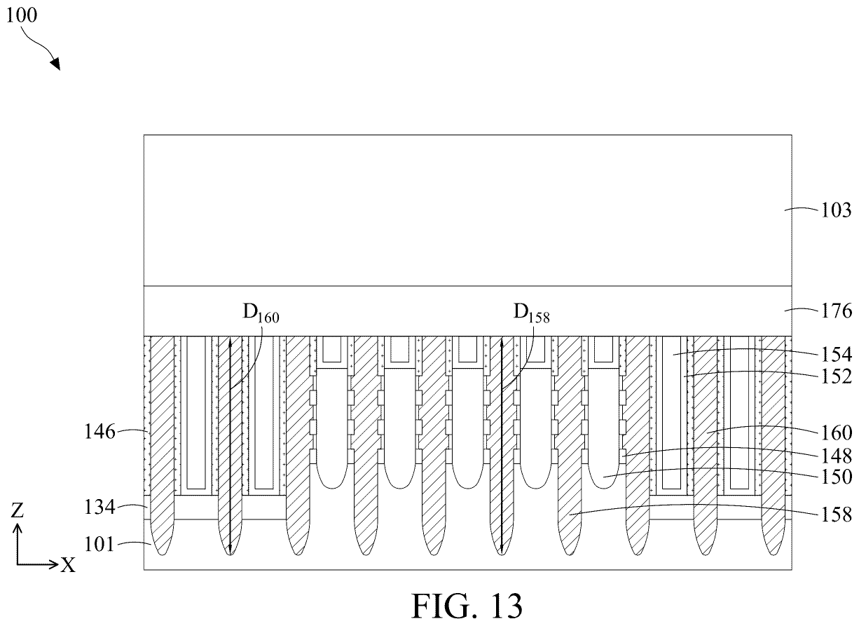

In operation 220, the interconnect structure 103 is formed, as shown in FIG. 13. The interconnect structure 103 includes a plurality of IMD layer formed over the TSV region 108, the boundary region 110, and the device area 106. In the device area 106, conductive vias and lines are formed in the IMD layers to provide power and signal connections to the devices. In the boundary region 110, continuous conductive lines and conductive vias may be formed in the IMD layers to form the guard ring 120. In the TSV region 108, as shown in FIG. 13, the interconnect structure does not include conductive features.

As discussed above, the isolation regions 158 and 160 may have different depths because of different composition. The isolation regions 158 have a depth D₁₅₈ and the isolation regions 160 have a depth D₁₆₀. In some embodiments, a ratio of the depth D₁₆₀ over the depth D₁₅₈ is in a range between about 30% and about 80%.

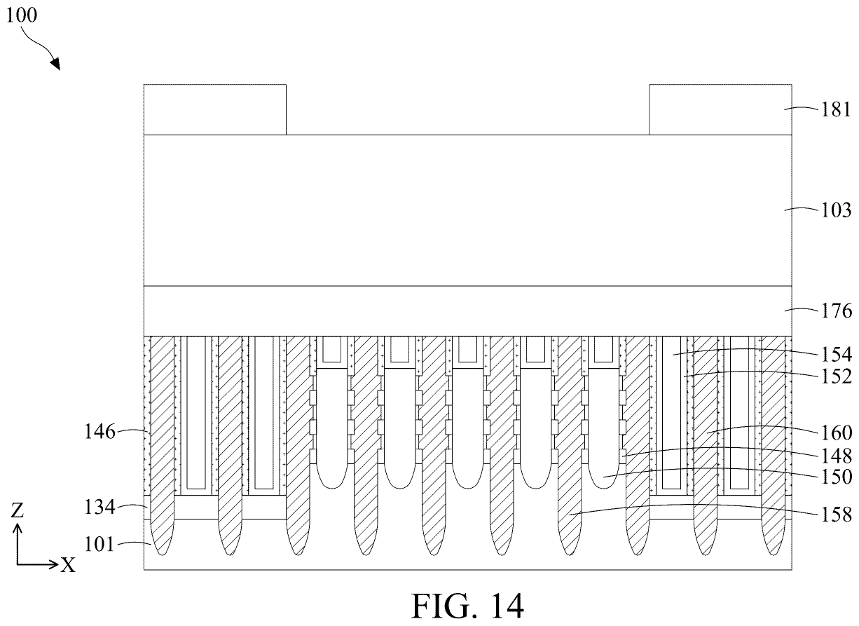

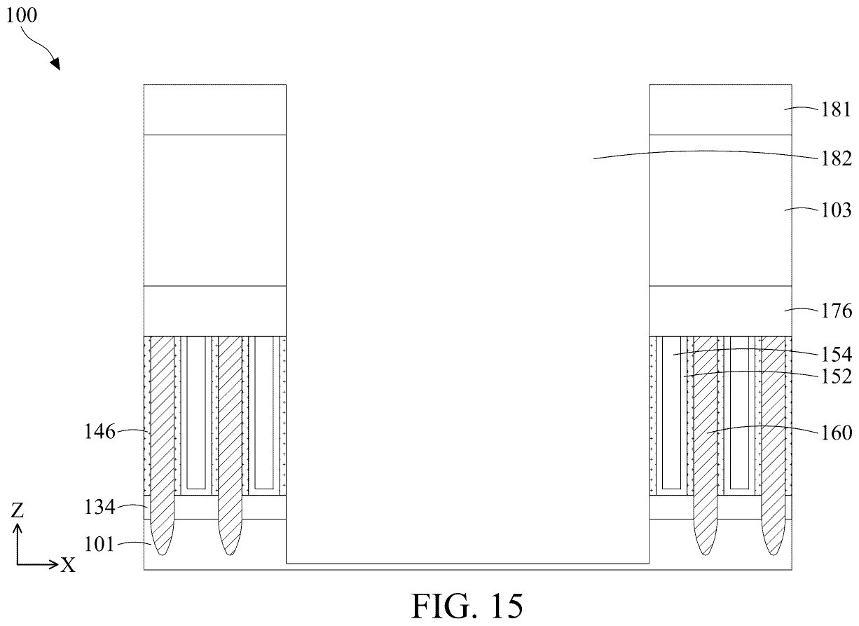

In operation 222, a TSV recess 182 is formed in the TSV region 108, as shown in FIGS. 14 and 15. The TSV recess 182 extends through the material layers in the TSV region 108, such as the epitaxial source/drain regions 150, the isolation regions 134, and the isolation regions 158. As an example, the TSV recess 182 may be formed by forming a patterned mask 181 over the interconnect structure 103, with the pattern of the mask corresponding to the TSV recess 182. One or more etching processes may be performed to extend the pattern of the patterned mask through the interconnect structure 103 and into the substrate 101, forming the TSV recess 182. Other techniques, such as milling, laser techniques, a combination thereof, and/or the like, may also be used. The TSV recess 182 may be formed extending into the substrate 101 at least further than the isolation regions 156. In some embodiments, the TSV recess 182 extends to a depth greater than the eventual desired thickness of the substrate 101. For example, in some embodiments, the back side of the substrate 101 may be thinned to expose the TSV structure 114. In some embodiments, the TSV recess 182 is formed within the end isolation region 158 in place of the end sacrificial gate stacks 136e.

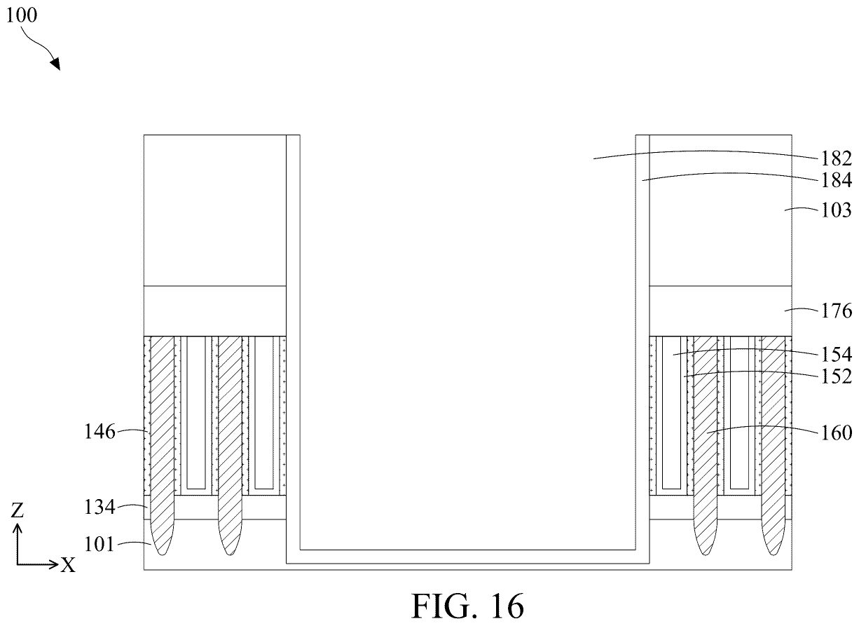

In operation 224, a liner layer 184 is formed on the surfaces of the TSV recesses, as shown in FIG. 16. In some embodiments, the liner layer 184 is formed of or comprises a dielectric material such as silicon nitride, silicon carbide, silicon oxynitride, silicon oxycarbide, or the like, or combinations thereof. The deposition method may include CVD, PECVD, Atomic Layer Deposition (ALD), Physical Vapor Deposition (PVD), or the like. In some embodiments, the liner layer 184 has good ability for electrical isolation and diffusion prevention and may prevent undesirable substances from penetrating through. The liner layer 184 may be a single dielectric layer or multiple dielectric layers. For example, the liner layer dielectric liner 184 may include a silicon oxide liner, and a silicon nitride liner over the silicon oxide liner. In some embodiments, the liner layer 184 may include a barrier layer. The barrier layer may be formed from an oxide, a nitride, or an oxynitride, such as titanium nitride, titanium oxynitride, tantalum nitride, tantalum oxynitride, tungsten nitride, a combination thereof, and/or the like. The liner layer 184 may comprise other materials or layers in other embodiments.

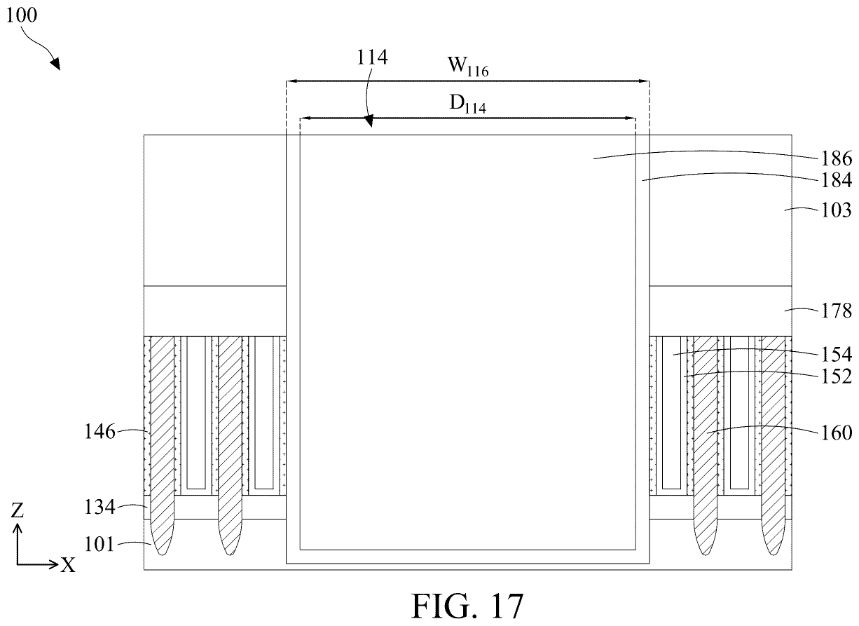

In operation 226, a fill material 186 may be deposited to fill the TSV recess 182, as shown in FIG. 17. The fill material 186 may comprise copper, tungsten, cobalt, aluminum, silver, gold, alloys, doped polysilicon, the like, or a combination thereof. In some embodiments, the fill material 186 may be formed by deposition or electroplating copper onto a seed layer, and then filling and overfilling the TSV recess 182. However, any suitable process such as CVD, PVD, or the like may be used. Once the TSV recess 182 has been filled, excess material outside of the TSV recess 182 may be removed using a planarization process such as a CMP process or the like. Remaining portions of the liner layer 184 and the fill material 186 form the TSV structure 114.

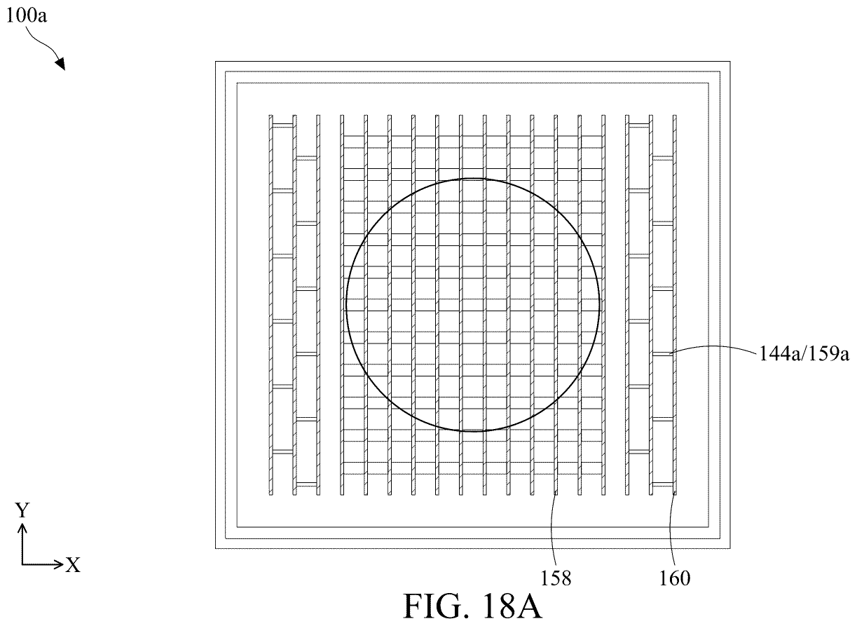

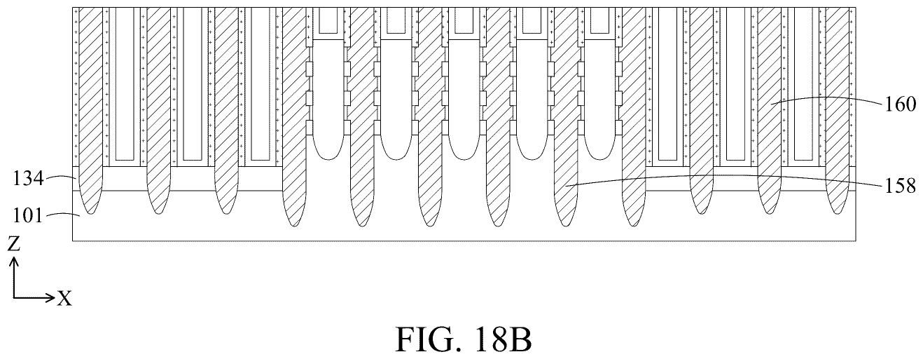

FIGS. 18A and 18B schematically demonstrate a semiconductor device structure 100a according to embodiments of the present disclosure. In some embodiments, the semiconductor device structure 100a is similar to the semiconductor device structure 100 except that the semiconductor structure 100a includes bridging structures 144a or isolation regions 159a arranged between the isolation regions 160 in a staggered manner. The staggered design may further reduce process loading.

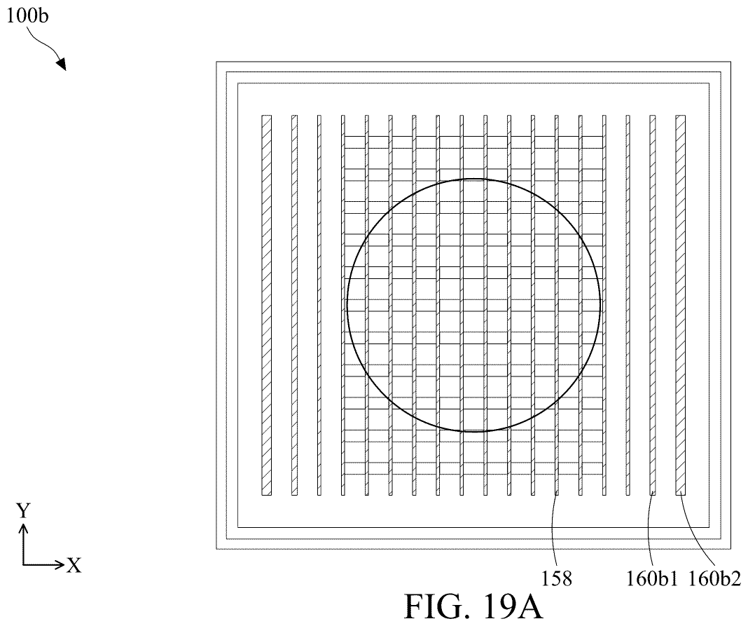

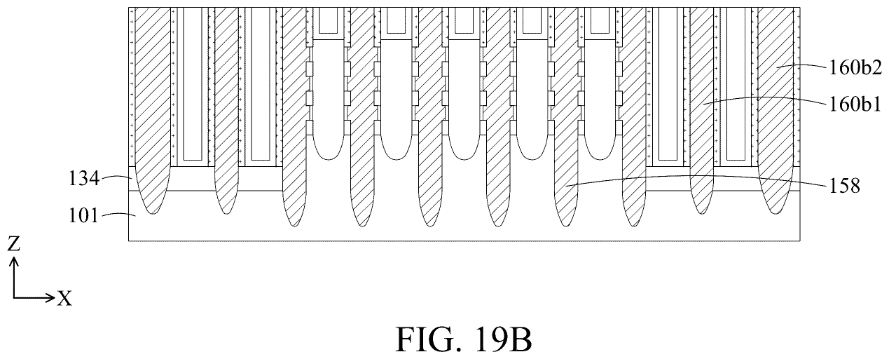

FIGS. 19A and 19B schematically demonstrate a semiconductor device structure 100b according to embodiments of the present disclosure. In some embodiments, the semiconductor device structure 100b is similar to the semiconductor device structure 100 except that the semiconductor structure 100b includes isolation regions 160b1, 160b2 without any bridging structures in between. In some embodiments, the isolation regions 160b1, 160b2 with increasing widths from the TSV structure 114 to the boundary region 110.

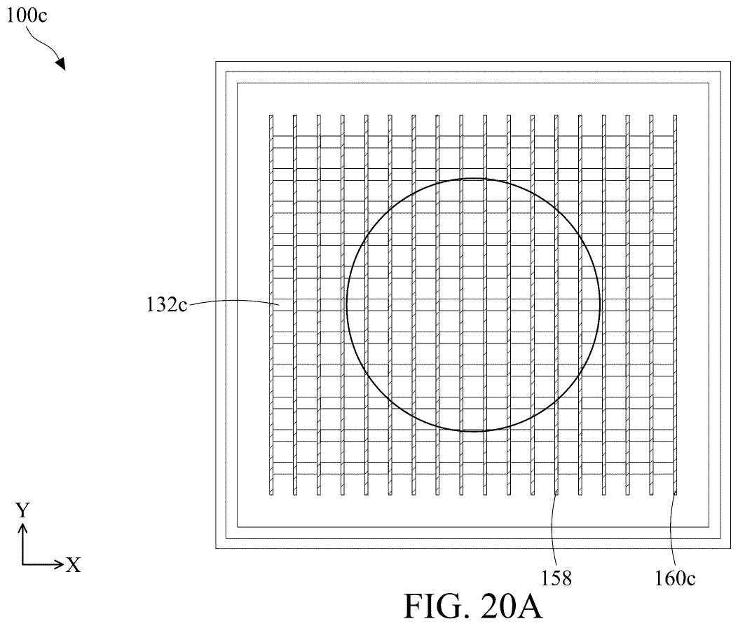

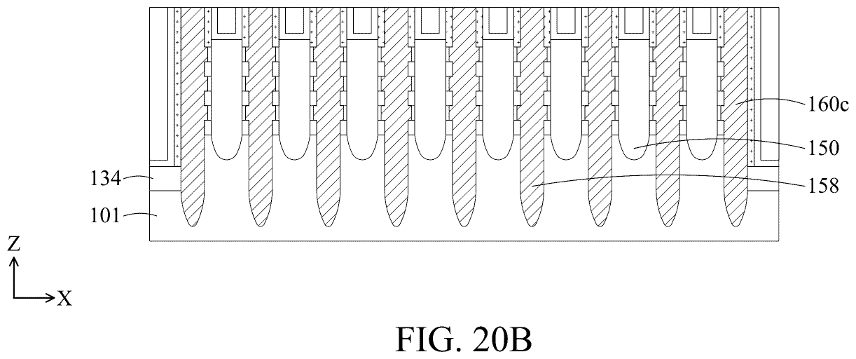

FIGS. 20A and 20B schematically demonstrate a semiconductor device structure 100c according to embodiments of the present disclosure. In some embodiments, the semiconductor device structure 100c is similar to the semiconductor device structure 100 except that the semiconductor structure 100c includes fin structures 132c extending across the entire width of the TSV region 108. The isolation regions 160c intersect with the fin structures 132c. The source/drain regions 150 are disposed between the isolation regions 160c.

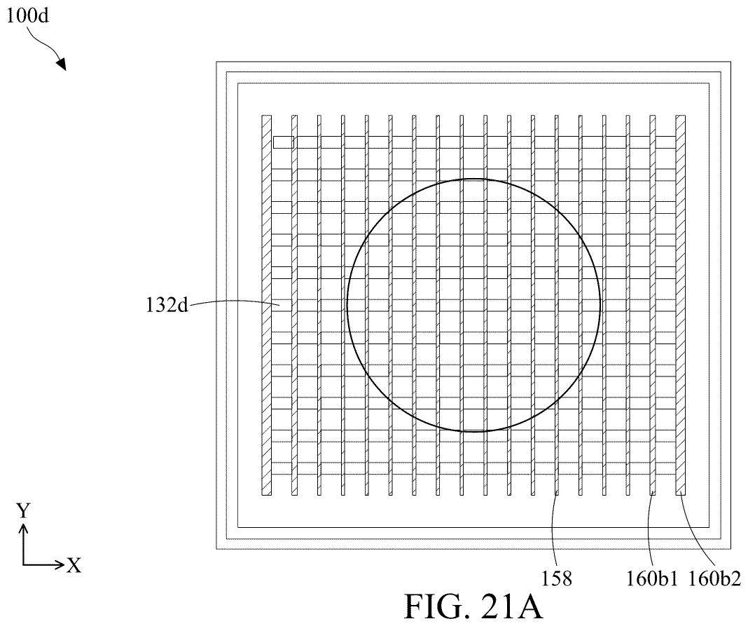

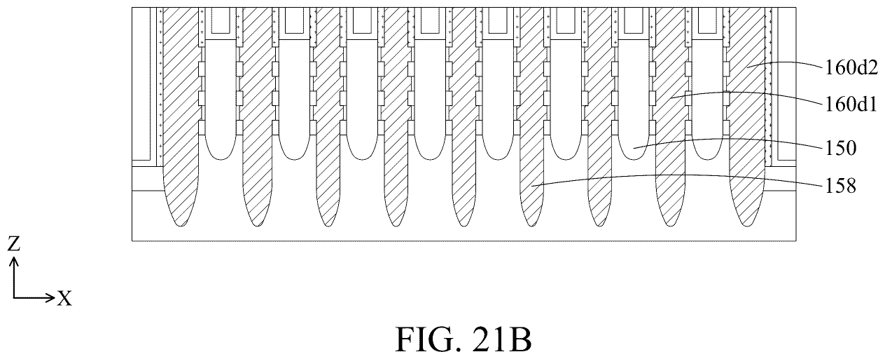

FIGS. 21A and 21B schematically demonstrate a semiconductor device structure 100d according to embodiments of the present disclosure. In some embodiments, the semiconductor device structure 100d is similar to the semiconductor device structure 100c except that the semiconductor structure 100d includes isolation regions 160b1, 160b2 with increasing widths from the TSV structure 114 to the boundary region 110.

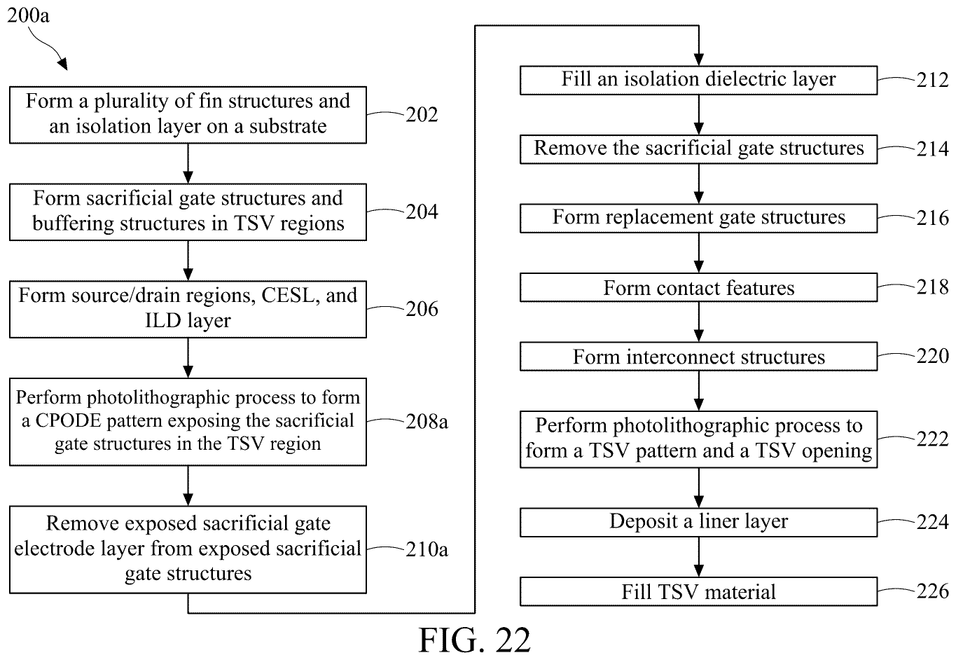

FIG. 22 is a flow chart of a method 200a for manufacturing of a semiconductor device according to embodiments of the present disclosure. The method 200a is similar to the method 200 except that method 200a includes operations 208a and 210a forming a different CPODE process. Particularly, the buffering structures 142, 144 are not exposed by the CPODE pattern formed in operation 208a. In other words, the CPODE process only forms isolation regions place of the sacrificial gate stacks 136. In some embodiments, the buffering structures 142, 144 are subsequent removed during replacement process, in operations 214 and 216. In other embodiments, the buffering structures 142, 144 may remain in the semiconductor device structure.

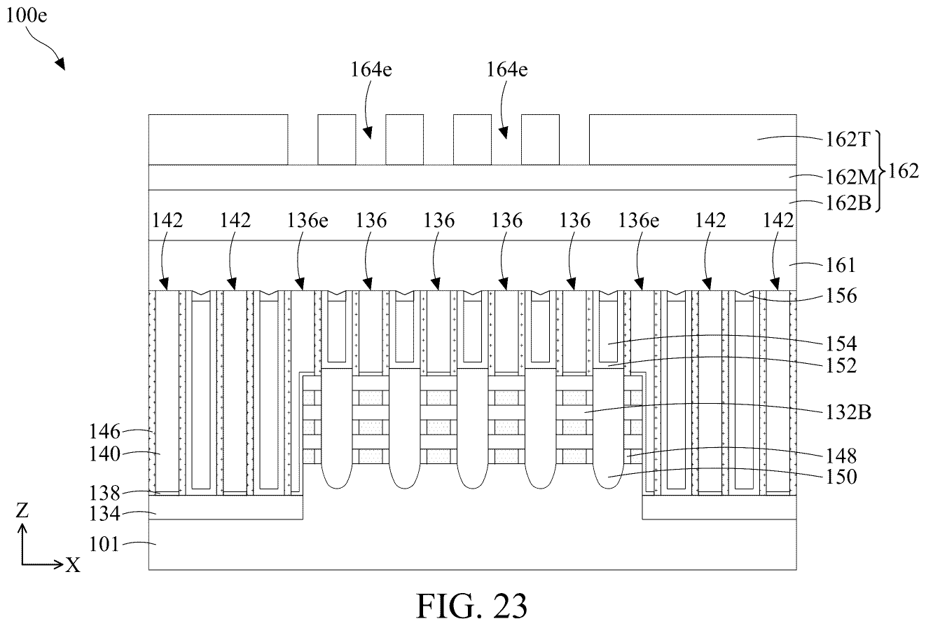

FIGS. 23, 24, 25, 26, 27A, 27B, and 28 schematically illustrate various stages of manufacturing the semiconductor device structure 100e using the method 200a.

In operation 208a, a CPODE pattern is formed over the TSV region 108, as shown in FIG. 23. The top layer 162B is patterned to include openings 164 aligned with the sacrificial gate stacks 136. The buffering structures 142 are covered by the top layer 162T, not exposed.

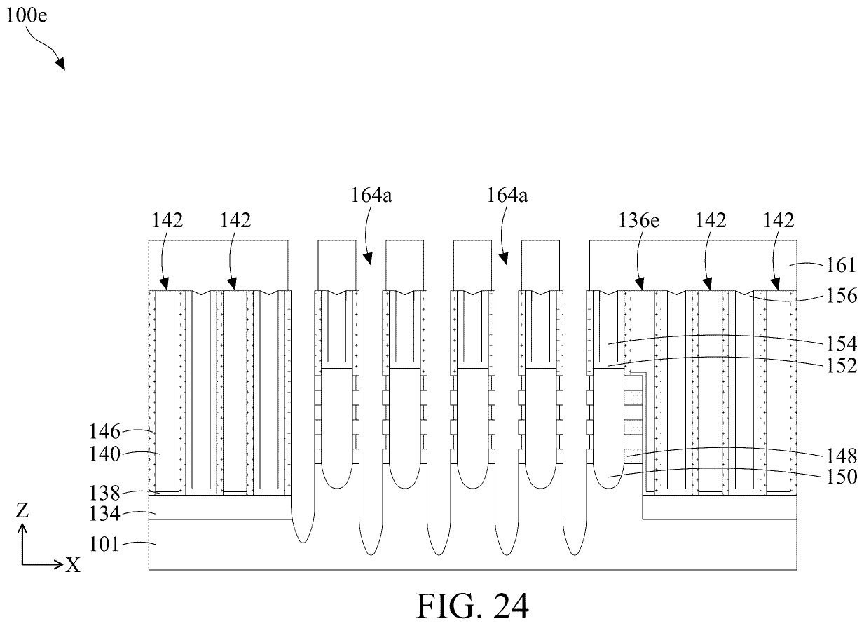

In operation 210a, trenches 164a are formed through various layers to the substrate 201 using the openings 164 in the patterned photoresist layer using one or more etching processes, as shown in FIG. 24. The buttering structures 142 and bridging structures 144 remain intact.

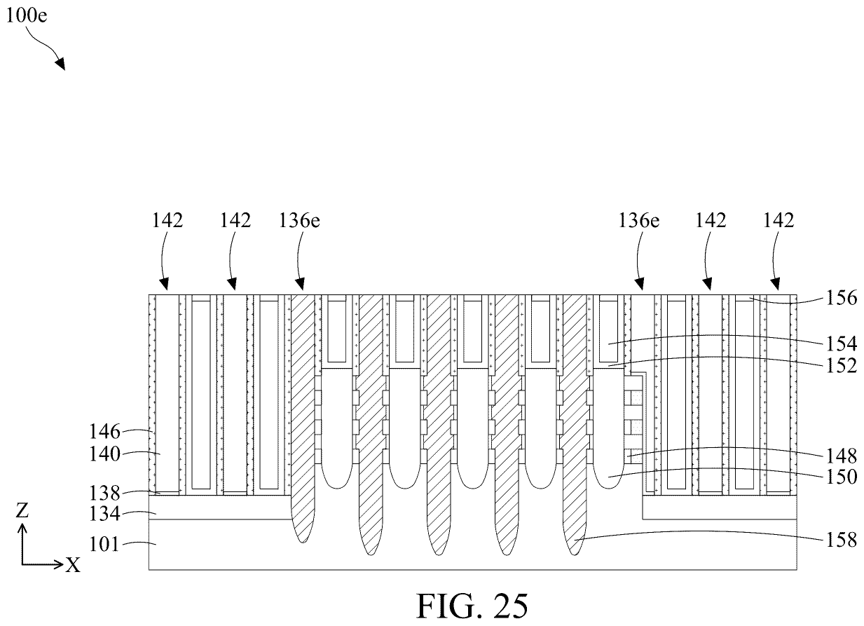

In operation 212, the trenches 164a are filled with dielectric material forming the isolation regions 158 as shown in FIG. 25.

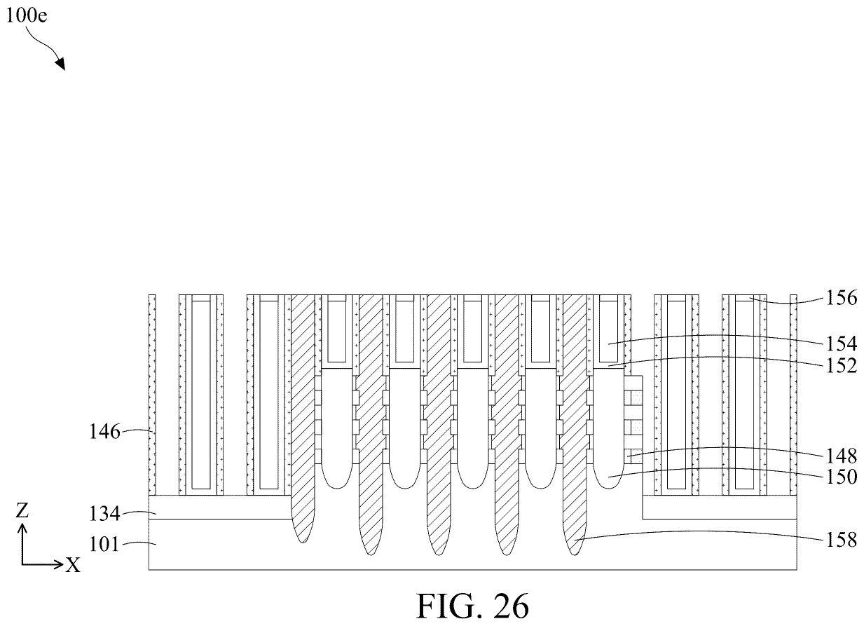

In operation 214, the sacrificial gate electrode layer 140 and the sacrificial gate dielectric layer 138 in the buffering structures 142 and bridging structures 144 are removed, as shown in FIG. 26. The isolation region 134 is exposed at bottoms of the openings vacated by the buffering structures 142 and bridging structures 144.

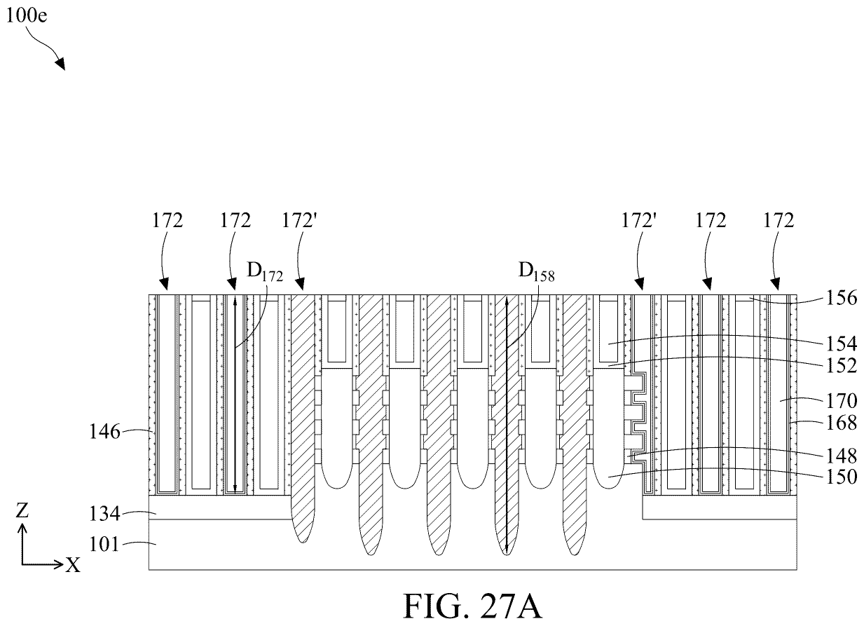

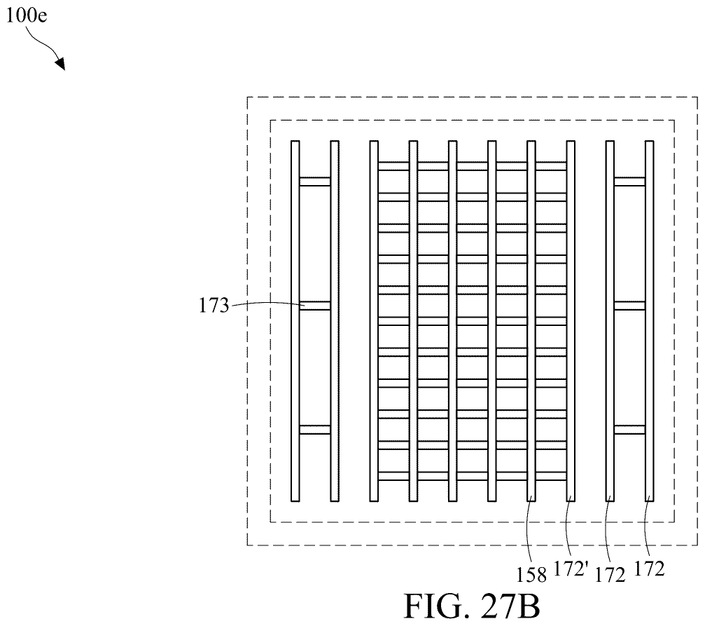

In operation 216, the gate dielectric layers 168 and gate electrode layer 170 are deposited in place of the buffering structures to form the replacement gate structures 172, as shown in FIG. 27A. FIG. 27B is a schematic top view of the semiconductor device structure 100e. As shown in FIG. 27B, the bridging structures 144 are also replaced with the gate dielectric layers 168 and gate electrode layer 170, forming bridging gate structures 173.

As shown in FIG. 27A, the isolation regions 158 and the gate structures 172 have different depths. The gate structures 172 have a depth D₁₇₂. In some embodiments, a ratio of the depth D₁₇₂ over the depth D₁₅₈ is in a range between about 10% and about 60%.

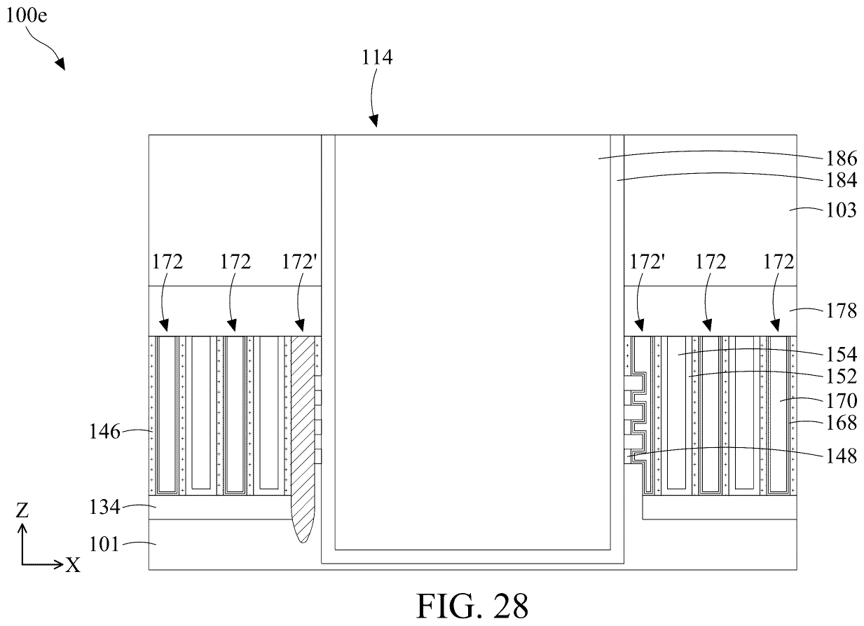

FIG. 28 schematically illustrates the semiconductor device structure 100e after the TSV structure 114 is formed. As shown in FIG. 28, metallic layers, e.g. the gate electrode layer 170, remain in the TSV region 108 and outside the TSV structure 114.

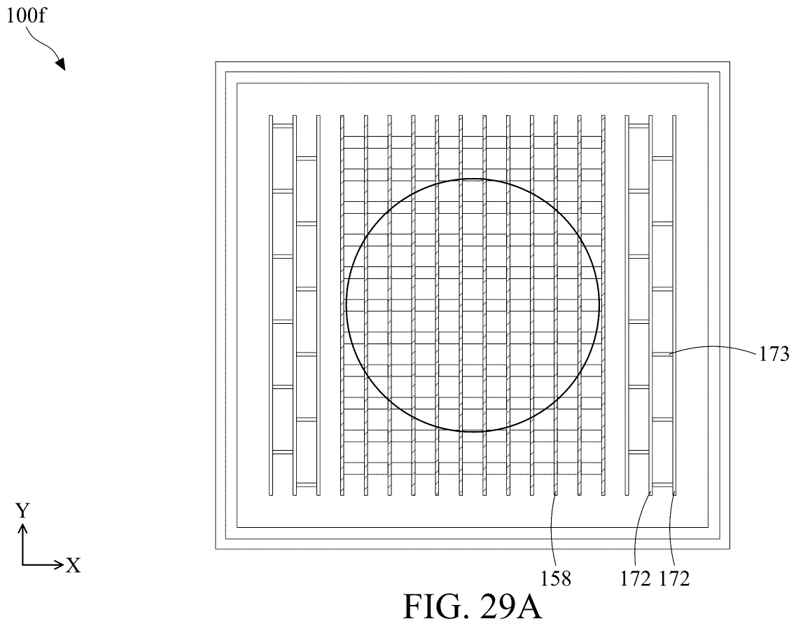

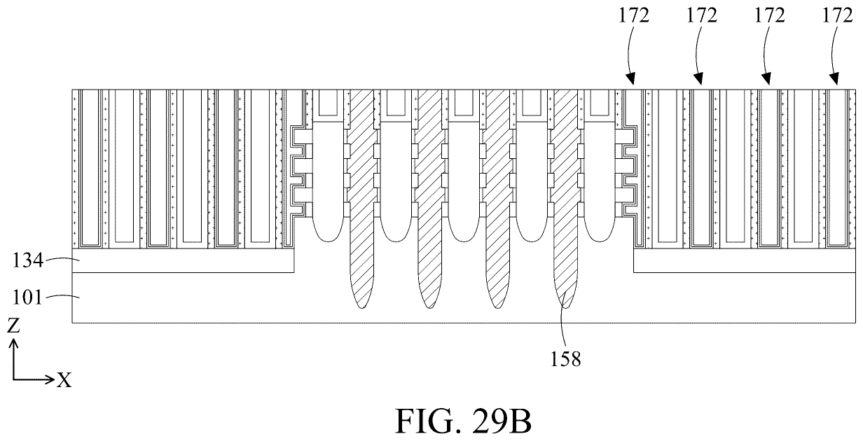

FIGS. 29A and 29B schematically demonstrate a semiconductor device structure 100f according to embodiments of the present disclosure. In some embodiments, the semiconductor device structure 100f is similar to the semiconductor device structure 100e except that the semiconductor structure 100f includes bridging gate structures 173 arranged between the gate structures 172 in a staggered manner. The staggered design may further reduce process loading.

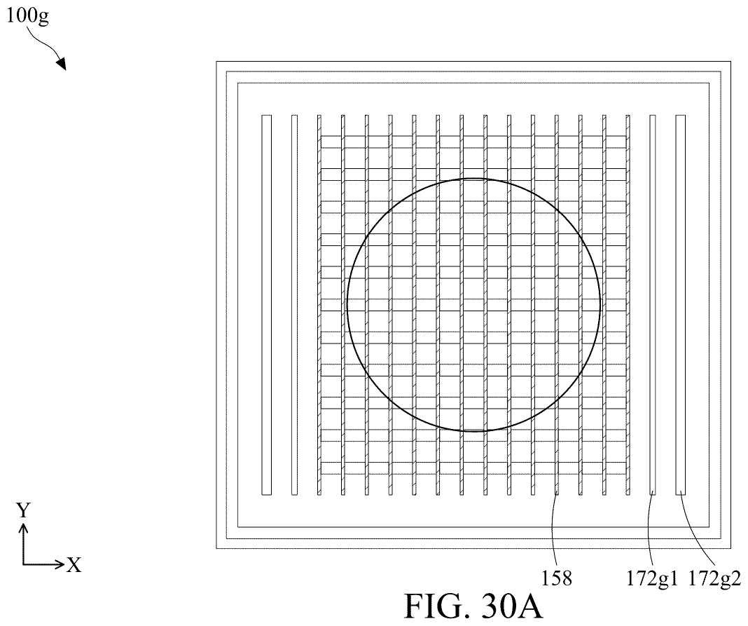

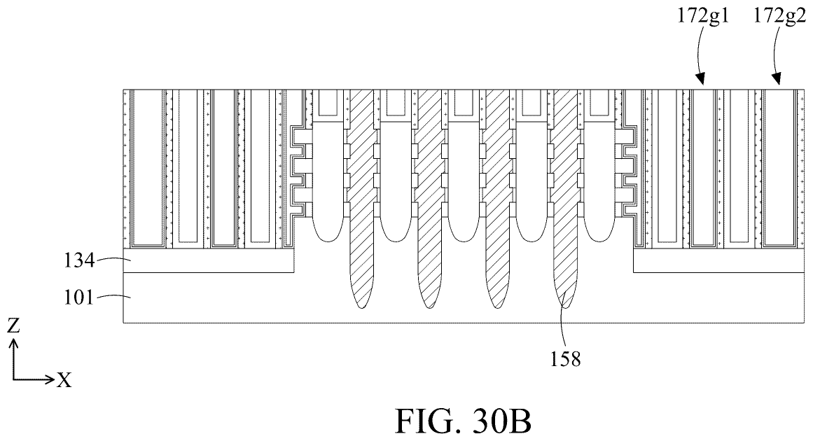

FIGS. 30A and 30B schematically demonstrate a semiconductor device structure 100g according to embodiments of the present disclosure. In some embodiments, the semiconductor device structure 100g is similar to the semiconductor device structure 100e except that the semiconductor structure 100g includes gate structures 172g1, 172g2 without any bridging structures in between. In some embodiments, the gate structures 172g1, 172g2 with increasing widths from the TSV structure 114 to the boundary region 110.

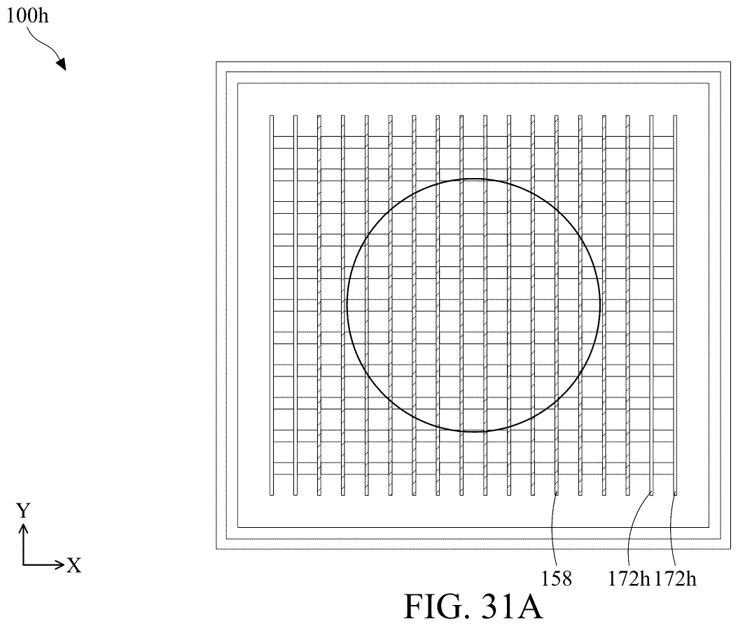

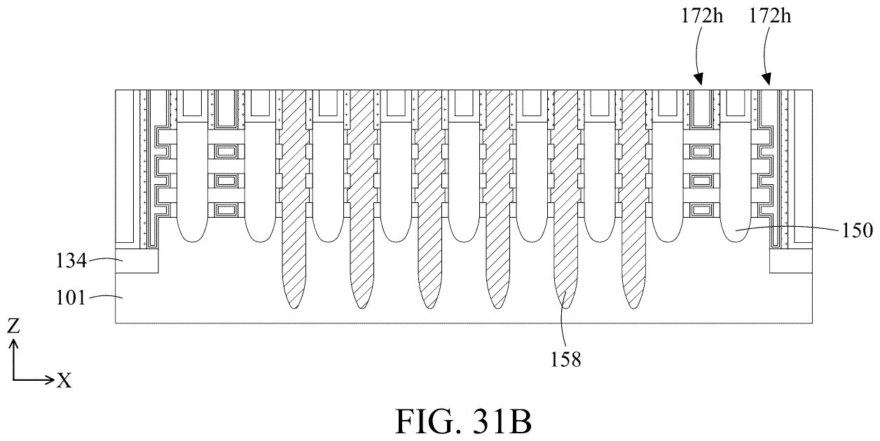

FIGS. 31A and 31B schematically demonstrate a semiconductor device structure 100h according to embodiments of the present disclosure. In some embodiments, the semiconductor device structure 100h is similar to the semiconductor device structure 100e except that the semiconductor structure 100h includes fin structures 132c extending across the entire width of the TSV region 108. The gate structures 172h intersect with the fin structures 132c. The source/drain regions 150 are disposed between the gate structures 172h.

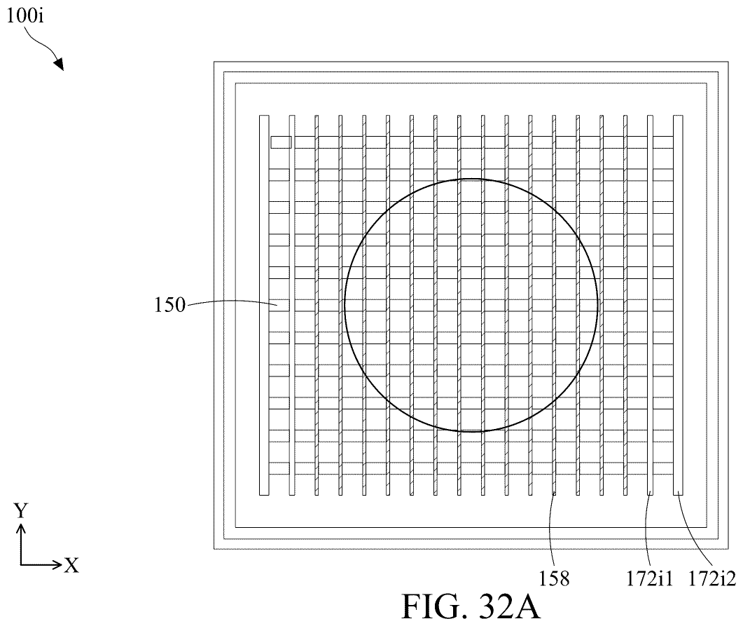

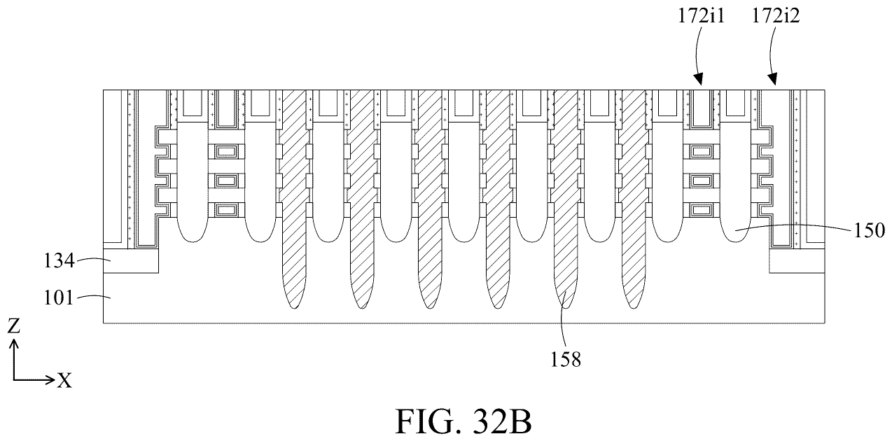

FIGS. 32A and 32B schematically demonstrate a semiconductor device structure 100i according to embodiments of the present disclosure. In some embodiments, the semiconductor device structure 100i is similar to the semiconductor device structure 100h except that the semiconductor structure 100i includes gate structures 172i1, 172i2 with increasing widths from the TSV structure 114 to the boundary region 110.

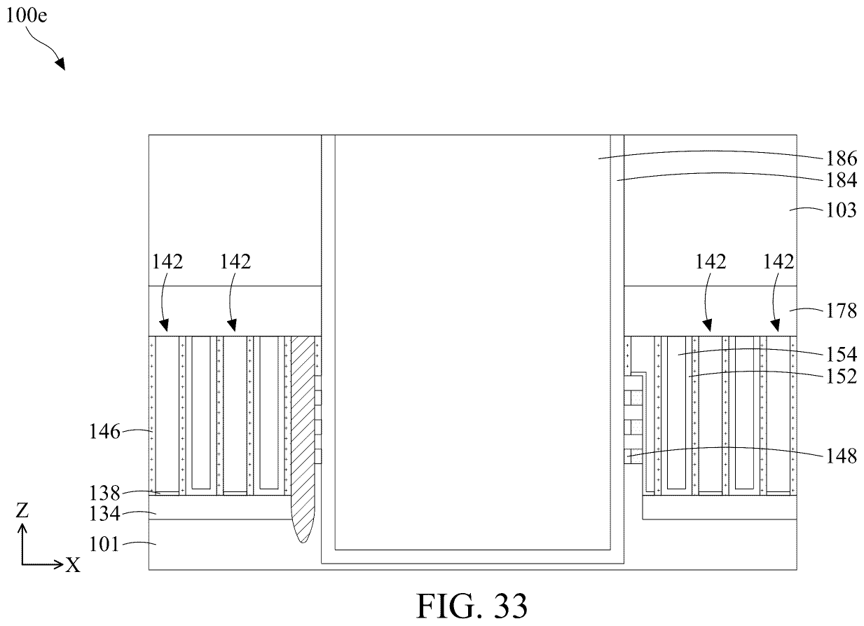

FIG. 33 schematically demonstrates a semiconductor device 100j according to embodiments of the present disclosure. The semiconductor device structure 100j is similar to the semiconductor device structure 100e except that the buffering structures 142 and the bridging structures 144 remain in the semiconductor structure 100j instead of being replaced by the replacement gate structures. Similarly, the semiconductor device structure 100f, 100g, 100h, and 100i may be modified by keeping the buffering structures 142.

Even though GAA devices are discussed, embodiments of the present disclosure can be applied to FinFET devices.

Various embodiments or examples described herein offer multiple advantages over the state-of-art technology. By introducing buffering structures adjacent the end gate structures of the dummy device in the TSV region, residual metallic material may be eliminated, thereby, avoiding arcing in fabrication of TSV structures.

Some embodiments of the present provide a semiconductor device structure, comprising: a substrate having a through silicon via (TSV) region, wherein TSV region includes a central section and an end section; a device layer formed on the substrate, wherein the device layer comprises: a plurality of isolation regions extending along a first direction and disposed in the central section; a plurality of source/drain regions disposed between the plurality of isolation regions; a first buffering structure disposed in the end section, wherein the first buffering structure is disposed along the first direction and adjacent to the plurality of isolation regions; and a TSV structure disposed in the device layer and the substrate, wherein the TVS structure is disposed within the central section of the TSV region.

Some embodiments of the present disclosure provide a method, comprising: forming a fin structure on a substrate; forming a plurality of sacrificial gate stacks over the fin structure, wherein the plurality of sacrificial gate stacks comprises a first end gate stack disposed over a first end of the fin structure, a second end gate stack disposed on a second end of the fin structure, and interior gate stacks disposed between the first end gate stack and the second end gate stack; forming a first buffering structure adjacent the first end gate stack and a second buffering structure adjacent the second end gate stack, wherein the first and second buffering structures are parallel to the plurality of sacrificial gate stacks; recess etching the fin structure not covered by the plurality of sacrificial gate stacks; forming source/drain regions between the plurality of sacrificial gate stacks; forming a first plurality of isolation recesses by removing the plurality of sacrificial gate stacks, portions of the fin structure under the plurality of gate sacrificial gate stacks, and portions of the substrate; forming a plurality of first isolation regions by filling a dielectric material in the plurality of first isolation recesses; forming a through substrate via (TSV) opening in the plurality of first isolation regions and the source/drain regions; and filling the TSV opening with a conductive material.

Some embodiments of the present disclosure provide a semiconductor device structure, comprising: a plurality of dummy devices comprising: a plurality of isolation regions extending along a first direction; and a plurality of source/drain regions disposed between the plurality of isolation regions; a first buffering structure disposed adjacent the plurality of dummy devices at a first side; a second buffering structure disposed adjacent the plurality of dummy devices at a second side, wherein the first and second buffering structures are parallel to the plurality of isolation regions; a guard ring disposed around the plurality of dummy devices, the first buffering structure, and the second buffering structure; and a through substrate via (TSV) structure disposed in the plurality of dummy devices.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a substrate having a through silicon via (TSV) region, wherein TSV region includes a central section and an end section;
a device layer formed on the substrate, wherein the device layer comprises:
a plurality of isolation regions extending along a first direction and disposed in the central section;
a plurality of source/drain regions disposed between the plurality of isolation regions;
a first buffering structure disposed in the end section, wherein the first buffering structure is disposed along the first direction and adjacent to the plurality of isolation regions; and
a TSV structure disposed in the device layer and the substrate, wherein the TVS structure is disposed within the central section of the TSV region.

2. The semiconductor device structure of claim 1, wherein the substrate further comprises a boundary region disposed around the TSV region, and a guard ring is formed in the boundary region.

3. The semiconductor device structure of claim 1, further comprising a second buffering structure disposed in the end section, wherein the first buffering structure is disposed between the second buffering structure and the plurality of isolation region.

4. The semiconductor device structure of claim 3, further comprising a first bridging structure disposed between the first and second buffering structures, wherein the first bridging structure extends along a second direction.

5. The semiconductor device structure of claim 4, further comprising a third buffering structure disposed in the end section, wherein the second buffering structure is disposed between the first buffering structure and the third buffering structure.

6. The semiconductor device structure of claim 5, further comprising a second bridging structure disposed between the third and second buffering structures, wherein the second bridging structure extends along the second direction.

7. The semiconductor device structure of claim 6, wherein the first and second bridging structures are arranged along a line in the second direction.

8. The semiconductor device structure of claim 6, wherein the first and second bridging structures are staggered.

9. The semiconductor device structure of claim 1, wherein the first buffering structure comprises a dielectric filling material.

10. The semiconductor device structure of claim 1, wherein the first buffering structure comprises a gate dielectric layer and a gate electrode layer disposed on the gate dielectric layer.

11. The semiconductor device structure of claim 4, wherein the first bridging structure and the first buffering structure include the same material.

12. The semiconductor device structure of claim 4, wherein the first bridging structure and the first buffering structure are formed from different materials.

13. The semiconductor device structure of claim 2, further comprising an interconnect structure disposed over the device layer, wherein the TSV structure is disposed in the interconnect structure, and the guard ring is disposed in the interconnect structure surrounding the TSV structure.

14. A method, comprising:
forming a fin structure on a substrate;
forming a plurality of sacrificial gate stacks over the fin structure, wherein the plurality of sacrificial gate stacks comprises a first end gate stack disposed over a first end of the fin structure, a second end gate stack disposed on a second end of the fin structure, and interior gate stacks disposed between the first end gate stack and the second end gate stack;
forming a first buffering structure adjacent the first end gate stack and a second buffering structure adjacent the second end gate stack, wherein the first and second buffering structures are parallel to the plurality of sacrificial gate stacks;
recess etching the fin structure not covered by the plurality of sacrificial gate stacks;
forming source/drain regions between the plurality of sacrificial gate stacks;
forming a first plurality of isolation recesses by removing the plurality of sacrificial gate stacks, portions of the fin structure under the plurality of gate sacrificial gate stacks, and portions of the substrate;
forming a plurality of first isolation regions by filling a dielectric material in the plurality of first isolation recesses;
forming a through substrate via (TSV) opening in the plurality of first isolation regions and the source/drain regions; and
filling the TSV opening with a conductive material.

15. The method of claim 14, further comprising:
forming second isolation recesses by removing the first and second buffering structures.

16. The method of claim 15, further comprising:
forming second isolation regions by filling the dielectric material in the second isolation recesses.

17. The method of claim 15, further comprising:
depositing a gate dielectric layer in the second isolation recesses; and
filling a gate electrode layer in the second isolation recesses.

18. A semiconductor device structure, comprising:
a plurality of dummy devices comprising:
a plurality of isolation regions extending along a first direction; and
a plurality of source/drain regions disposed between the plurality of isolation regions;
a first buffering structure disposed adjacent the plurality of dummy devices at a first side;
a second buffering structure disposed adjacent the plurality of dummy devices at a second side, wherein the first and second buffering structures are parallel to the plurality of isolation regions;
a guard ring disposed around the plurality of dummy devices, the first buffering structure, and the second buffering structure; and
a through substrate via (TSV) structure disposed in the plurality of dummy devices.

19. The semiconductor device structure of claim 18, wherein the first and second buffering structures and the plurality of isolation regions are formed from the same material.

20. The semiconductor device structure of claim 18, wherein each of the first and second buffering structures comprises:
a gate dielectric layer; and
a gate electrode layer disposed on the gate dielectric layer.
